(19) United States
(12) Patent Application Publication
(10) Pub. No.: US 2007/0224547 A1
(43) Pub. Date: Sep. 27, 2007

(54) Method of processing substrate

(75) Inventor: Shusaku Kido, Izumi-shi (JP)

Correspondence Address: YOUNG & THOMPSON, 745 SOUTH 23RD STREET, 2ND FLOOR, ARLINGTON, VA, 22202, US

(73) Assignee: NEC LCD TECHNOLOGIES, LTD., KAWASAKI-SHI (JP)

(21) Appl. No.: 11/723,828

(22) Filed: Mar. 22, 2007

(30) Foreign Application Priority Data
Mar. 23, 2006 (JP) 2006-081467

(51) Int. Cl. G03F 7/26

(52) U.S. Cl. 430/322; 430/330

(57) ABSTRACT

A method of processing an organic film pattern formed on a substrate, includes, in sequence of, a fusion/deformation step of fusing and thereby deforming the organic film pattern, and a third removal step of removing at least a part of the fused and deformed organic film pattern.

### BACKGROUND OF THE INVENTION

1. Field of the Invention

The present invention relates to method of processing a substrate such as a semiconductor wafer and a LCD substrate, and chemical solution used in the method. Furthermore, the present invention relates to a method of fabricating a device such as a liquid crystal display (LCD) device including a vertical electric field type liquid crystal display device, a horizontal electric field type liquid crystal display device, a light-transmission type liquid crystal display device, a light-reflection type liquid crystal display device, and a half-transmission type liquid crystal display device, an EL display device, a field emission display device and a semiconductor device.

2. Description of the Related Art

A wiring in a circuit has been conventionally formed, for instance, by forming an organic film pattern on a semiconductor wafer, a liquid crystal display (LCD) substrate or other substrates, and etching an underlying film or the substrate with the organic film pattern being used as a mask to thereby pattern the underlying film. After the underlying film has been patterned, the organic film pattern is removed.

For instance, Japanese Patent Application Publication No. 2002-202619 has suggested a method of separating an organic film pattern, including exposing the organic film pattern to vapor of chemical solution to allow the chemical solution to penetrate the organic film pattern with the result of deformation of the organic film pattern, and separating the organic film pattern.

Japanese Patent Application Publication No. 2005-159293 has suggested an apparatus for processing a substrate, including a substrate carrier for carrying a substrate, a chemical-applying unit for applying chemical solution to the substrate, and a gas-applying unit for applying gas atmosphere to the substrate.

For instance, Japanese Patent Application Publications Nos. 2002-334830, 2005-159292 and 2005-159342 have suggested a method of processing a substrate, including the steps of processing an underlying film, deforming an organic film pattern, etching the underlying film with the deformed organic film pattern being used as a mask, and removing the organic film pattern.

Specifically, the suggested methods include a step of deforming an organic film pattern (hereinafter, referred to as “fusion/deformation step”, or referred to as “gas atmosphere step” because the “fusion/deformation step” is carried out by exposing a substrate to gas atmosphere), patterning an underlying film with the deformed organic film pattern being used as a mask, and removing the organic film pattern.

Namely, the suggested methods principally include the fusion/deformation step or the gas atmosphere step.

In order to stably carry out those steps, the methods may include steps of controlling (specifically, lowering) a temperature of a substrate to a suitable temperature, and heating the organic film pattern to be able to readily bake the organic film pattern after the organic film pattern has been deformed.

FIGS. 11A, 11B and 11C show steps to be carried out in the above-mentioned conventional methods.

As illustrated in FIG. 11A, the first conventional method of processing a substrate includes in sequence of a step S102 of controlling a temperature of a substrate, a step S103 of exposing an organic film pattern to gas atmosphere, a step S104 of heating the organic film pattern, and a step of S102 of heating the organic film pattern.

As illustrated in FIG. 11B, the second conventional method of processing a substrate includes in sequence of a first removal step J1, a step S102 of controlling a temperature of a substrate, a step S103 of exposing an organic film pattern to gas atmosphere, a step S104 of heating the organic film pattern, and a step of S102 of heating the organic film pattern.

As illustrated in FIG. 11C, the second conventional method of processing a substrate includes in sequence of a first removal step J1, a second removal step J2, a step S102 of controlling a temperature of a substrate, a step S103 of exposing an organic film pattern to gas atmosphere, a step S104 of heating the organic film pattern, and a step of S102 of heating the organic film pattern.

Each of the first removal step J1 and the second removal step J2 shown in FIGS. 11A, 11B and 11C is comprised of a first chemical solution step S1, an ashing step S7, and a second chemical solution step S5 alone or in combination (these steps are explained in detail later with reference to FIGS. 2 and 3).

Each of the first removal step J1 and the second removal step J2 is carried out in order to selectively remove an alterated layer or a deposited layer, or to remove an alterated layer or a deposited layer to thereby cause a non-alterated portion of an organic film pattern to appear.

The step S102 of controlling a temperature of a substrate may be omitted.

The step S103 of exposing an organic film pattern to gas atmosphere, in the conventional methods shown in FIGS. 11A, 11B and 11C, acts as a fusion/deformation step, namely, has a function of fusing and thereby deforming organic film pattern.

In the gas atmosphere step, an organic film pattern is exposed to gas atmosphere obtained by vaporizing an organic solvent such as alcohol (R—OH), alkoxyalcohol, ether (R—O—R, Ar—O—R, Ar—O—Ar), ester, ketone, glycol, alkylene glycol, and glycol ether (R indicates an alkyl group or a substituted alkyl group, Ar indicates a phenyl group or an aromatic ring other than a phenyl group), and thus, the organic solvent penetrates the organic film pattern. As a result, the organic film pattern is fused, and thus, liquidized or fluidized (hereinafter, referred to as “chemical solution fusion reflow”). Thus, the organic film pattern is deformed.

The fusion/deformation step causes an organic film pattern to deform in the range of 5 to 20 micrometers (it is possible to deform an organic film pattern by 100 micrometers or more).

However, since an organic film pattern is much deformed, if the organic film pattern is required to be accurately patterned, it would be necessary to accurately control the deformation of the organic film pattern.

In order to reduce a number of photolithography steps, there may be used an organic film pattern (specifically, a resist pattern) for forming a source and a drain in a channel. The fusion/deformation step is used for deforming two separate portions of the resist pattern located in the vicinity of a channel, corresponding to the source and drain, thereby unifying the separate two portions to each other.

It is necessary to cause much “chemical solution fusion reflow” in order to stably unify the separate two portions to each other. However, if “chemical solution fusion reflow” is carried out so much, a resist pattern associated with portions other than a channel, such as wirings, would be much fused and deformed.

Accordingly, it was necessary to design a resist pattern to have two portions having different thicknesses from each other, and to remove a thinner portion of the resist pattern before carrying out the fusion/deformation step.

However, since an organic film pattern would have an increased area due to the fusion/deformation step, it would be necessary to accurately control a time for carrying out the fusion/deformation step to thereby control accurately the deformation of an organic film patter, in order to prevent an area of the organic film pattern from increasing.

### SUMMARY OF THE INVENTION

In view of the above-mentioned problems, it is an object of the present invention to provide a method of processing a substrate which is capable of contracting an organic film pattern having an area having been increased due to fusion/deformation reflow.

In the method in accordance with the present invention, a fusion/deformation step (specifically, a gas atmosphere step) is carried out similarly to the conventional method, but thereafter, a part of an organic film pattern (for instance, a resist pattern) having an area having been increased more than necessary due to fusion/deformation reflow, that is, an unnecessary portion of an organic film pattern is removed.

Specifically, an unnecessary portion of an organic film pattern is removed by as ashing step and a chemical solution step alone or in combination. In the chemical solution step, there is used chemical solution having a function of developing an organic film pattern or a function of separating an organic film pattern.

Specifically, the present invention provides a method of processing an organic film pattern formed on a substrate, comprising, in sequence of, a fusion/deformation step of fusing and thereby deforming the organic film pattern, and a third removal step of removing at least a part of the fused and deformed organic film pattern.

A step of removing an alterated layer or a deposited layer formed on a surface of an organic film pattern may be carried out before the fusion/deformation step, if necessary.

Specifically, in the method in accordance with the present invention, after the fusion/deformation step has been carried out for fusing and thereby deforming an organic film pattern formed on a substrate, an unnecessary portion of the organic film pattern or a portion of the organic film pattern having an area having increased more than necessity is at least partially removed by various removal steps (defined in “third removal step” in claims).

In the conventional method, an area of an organic film pattern is only increased due to the fusion/deformation reflow, and an increasing rate is controlled by controlling a period of time during which the fusion/deformation reflow is carried out, for instance. In contrast, the present invention makes it possible to control an area of an organic film pattern in opposite ways. That is, the present invention provides the second control to an area of an organic film pattern by removing or contracting the organic film pattern after the fusion/deformation reflow was carried out, ensuring that the deformation of an organic film pattern can be accurately controlled.

In order to reduce a number of photolithography steps in the conventional method, there was used an organic film pattern (specifically, a resist pattern) for forming a source and a drain in a channel. The fusion/deformation step was used for deforming two separate portions of the resist pattern located in the vicinity of a channel, corresponding to the source and drain, thereby unifying the separate two portions to each other.

However, if the chemical solution fusion reflow caused by the fusion/deformation step is small, it was not possible to unify the separate two portions of an organic film pattern to each other, but there is less generated a portion of an organic film pattern having an area increased more than necessity. If the chemical solution fusion reflow caused by the fusion/deformation step is large, there was much generated a portion of an organic film pattern having an area increased more than necessity, but it is possible to unify the separate two portions of an organic film pattern to each other.

In contrast, when the method in accordance with the present invention is used for reducing a number of photolithography steps, the chemical solution reflow is caused sufficiently large due to the fusion/deformation step, and then, a deformed portion of the organic film pattern is removed or contracted in area, thereby the deformed portion of the organic film pattern would have a desired area. Thus, the method in accordance with the present invention provides only the merits in the conventional method.

For instance, the fusion/deformation step is carried out by causing chemical solution (for instance, organic solvent) to penetrate an organic film pattern formed on a substrate, to thereby deform the organic film pattern.

For instance, the fusion/deformation step may be comprised of a gas atmosphere step in which chemical solution (for instance, organic solvent) is gasified by nitrogen (N₂) bubbling, and a substrate is exposed to the thus generated gas atmosphere.

Specifically, the fusion/deformation step is carried out in order to enlarge an area of an organic film pattern, unify organic film patterns disposed adjacent to each other, planarize an organic film pattern, or deform an organic film pattern so as to turn the organic film pattern into an electrically insulating film covering a circuit pattern formed on a substrate.

For instance, an organic film pattern to be first formed on a substrate may be formed by printing or photolithography.

Furthermore, it is preferable that an organic film pattern is comprised of a photosensitive organic film, in which case, the photosensitive film may be a positive type photosensitive organic film or a negative type photosensitive organic film. It is preferable that the positive type photosensitive organic film contain novolak resin as a primary constituent. However, the positive type photosensitive organic film may be composed of resin other than novolak.

The photosensitive organic film may be alkali-soluble when exposed to light.

An organic film pattern may be comprised of (a) a film formed by patterning an underlying film with the organic film pattern being used as a mask before the fusion/deformation step is carried out, (b) an underlying film patterned by etching with the organic film pattern being used as a mask, wherein the underlying film is patterned again with the thus patterned organic film pattern being used as a mask, or (c) an organic film pattern to which at least one of a light-exposure step, a development step, a wet-etching step, and a dry-etching step is applied before the fusion/deformation step is carried out.

The above-mentioned alterated layer formed on an organic film pattern is caused when (a) a surface of an organic film pattern is alterated due to at least one of aging, thermal oxidation and heat curing, (b) a surface of an organic film pattern is alterated due to etchant used for wet-etching, (c) a surface of an organic film pattern is alterated due to dry-etching or ashing, or (d) a surface of an organic film pattern is alterated due to deposition caused by dry-etching.

The above-mentioned deposited layer is formed on a surface of an organic film pattern by dry-etching, for instance.

In a first aspect, the method of a processing a substrate includes a fusion/deformation step (that is, a gas atmosphere step in which an organic film pattern is exposed to gas atmosphere generated by vaporizing organic solvent), and a third removal step.

Specifically, the method in accordance with the present invention in a first aspect includes, in sequence of, a fusion/deformation step (hereinafter, referred also to “a gas atmosphere step”) for fusing and thereby deforming an organic film pattern, and a third removal step.

Furthermore, in order to stably carry out those steps, the method may include steps of controlling (specifically, lowering) a temperature of a substrate to a suitable temperature, and heating the organic film pattern to be able to readily bake the organic film pattern after the organic film pattern has been deformed.

FIG. 1A is a flowchart showing steps to be carried out in the method in accordance with the present invention in a first aspect.

As illustrated in FIG. 1A, the method includes, in sequence of, a temperature-controlling step S2 of controlling a temperature of a substrate or an organic film pattern, a gas-atmosphere step S3 of exposing the organic film pattern to gas atmosphere, a second heating step S4 of heating the organic film pattern, a temperature-controlling step S2 of controlling a temperature of a substrate or the organic film pattern, a third removal step J3, and a third heating step S8.

The temperature-controlling step S2, the second heating step S4, and the third heating step S8 embraced with broken-line brackets in FIG. 1A may be omitted.

Furthermore, the second heating step S4, the third heating step S8, and the temperature-controlling step S2 may be carried out by changing a temperature range in a processing unit prepared for carrying out those steps.

As explained above, the method in accordance with the present invention in a first aspect necessarily includes the gas-atmosphere step S3 and the third removal step J3, and other steps may be omitted, if necessary.

The method in accordance with the present invention in a second aspect includes a first removal step, a fusion/deformation step (that is, a gas atmosphere step in which an organic film pattern is exposed to gas atmosphere generated by vaporizing organic solvent), and a third removal step.

Specifically, the method in accordance with the present invention in a second aspect includes, in sequence of, a first removal step, a fusion/deformation step (hereinafter, referred also to “a gas atmosphere step”) for fusing and thereby deforming an organic film pattern, and a third removal step.

Furthermore, in order to stably carry out those steps, the method may include steps of controlling (specifically, lowering) a temperature of a substrate to a suitable temperature before the gas atmosphere step is carried out, and heating the organic film pattern to be able to readily bake the organic film pattern after the organic film pattern has been deformed.

FIG. 1B is a flowchart showing steps to be carried out in the method in accordance with the present invention in a second aspect.

As illustrated in FIG. 1B, the method includes, in sequence of, a first removal step J1, a temperature-controlling step S2 of controlling a temperature of a substrate or an organic film pattern, a gas-atmosphere step S3 of exposing the organic film pattern to gas atmosphere, a second heating step S4 of heating the organic film pattern, a temperature-controlling step S2 of controlling a temperature of a substrate or the organic film pattern, a third removal step J3, and a third heating step S8.

The temperature-controlling step S2, the second heating step S4, and the third heating step S8 embraced with broken-line brackets in FIG. 1B may be omitted.

Furthermore, the second heating step S4, the third heating step S8, and the temperature-controlling step S2 may be carried out by changing a temperature range in a processing unit prepared for carrying out those steps.

As explained above, the method in accordance with the present invention in a second aspect necessarily includes the first removal step J1, the gas-atmosphere step S3 and the third removal step J3, and other steps may be omitted, if necessary.

The method in accordance with the present invention in a third aspect includes a first removal step, a second removal step, a fusion/deformation step (that is, a gas atmosphere step in which an organic film pattern is exposed to gas atmosphere generated by vaporizing organic solvent), and a third removal step.

Specifically, the method in accordance with the present invention in a third aspect includes, in sequence of, a first removal step, a second removal step, a fusion/deformation step (hereinafter, referred also to “a gas atmosphere step”) for fusing and thereby deforming an organic film pattern, and a third removal step.

Furthermore, in order to stably carry out those steps, the method may include steps of controlling (specifically, lowering) a temperature of a substrate to a suitable temperature before the gas atmosphere step is carried out, and heating the organic film pattern to be able to readily bake the organic film pattern after the organic film pattern has been deformed.

FIG. 1C is a flowchart showing steps to be carried out in the method in accordance with the present invention in a third aspect.

As illustrated in FIG. 1C, the method includes, in sequence of, a first removal step J1, a second removal step J2, a temperature-controlling step S2 of controlling a temperature of a substrate or an organic film pattern, a gas-atmosphere step S3 of exposing the organic film pattern to gas atmosphere, a second heating step S4 of heating the organic film pattern, a temperature-controlling step S2 of controlling a temperature of a substrate or the organic film pattern, a third removal step J3, and a third heating step S8.

The temperature-controlling step S2, the second heating step S4, and the third heating step S8 embraced with broken-line brackets in FIG. 1C may be omitted.

Furthermore, the second heating step S4, the third heating step S8, and the temperature-controlling step S2 may be carried out by changing a temperature range in a processing unit prepared for carrying out those steps.

As explained above, the method in accordance with the present invention in a third aspect necessarily includes the first removal step J1, a second removal step J2, the gas-atmosphere step S3 and the third removal step J3, and other steps may be omitted, if necessary.

Hereinbelow is explained the above-mentioned first removal step J1.

FIGS. 2A, 2B and 2C are flowcharts each showing a step or steps to be carried out in examples of the first removal step J1.

As illustrated in FIG. 2A, a first example of the first removal step J1 is comprised of a first chemical solution step S1 for applying chemical solution to an organic film pattern.

As illustrated in FIG. 2B, a second example of the first removal step J1 is comprised of an ashing step S7 for ashing an organic film pattern.

As illustrated in FIG. 2C, a third example of the first removal step J1 is comprised of an ashing step S7, and a first chemical solution step S1.

Hereinbelow is explained the above-mentioned second removal step J2.

FIGS. 3A, 3B and 3C are flowcharts each showing a step or steps to be carried out in examples of the second removal step J2.

As illustrated in FIG. 3A, a first example of the second removal step J2 is comprised of a second chemical solution step S5 for applying chemical solution to an organic film pattern.

As illustrated in FIG. 3B, a second example of the second removal step J2 is comprised of an ashing step S7 for ashing an organic film pattern.

As illustrated in FIG. 3C, a third example of the second removal step J2 is comprised of an ashing step S7, and a second chemical solution step S5.

Hereinbelow is explained the above-mentioned third removal step J3.

FIGS. 4A, 4B, 4C and 4D are flowcharts each showing a step or steps to be carried out in examples of the third removal step J3.

As illustrated in FIG. 4A, a first example of the third removal step J3 is comprised of the above-mentioned second chemical solution step S5 for applying chemical solution to an organic film pattern.

As illustrated in FIG. 4B, a second example of the third removal step J3 is comprised of the above-mentioned ashing step S7 for ashing an organic film pattern.

As illustrated in FIG. 4C, a third example of the third removal step J3 is comprised of the first chemical solution step S1, and the second chemical solution step S5.

As illustrated in FIG. 4D, a fourth example of the third removal step J3 is comprised of the above-mentioned ashing step S7, and the second chemical solution step S5.

The first to third removal steps are carried out for the following purposes:

(A) the above-mentioned alterated or deposited layer is selectively removed;

(B) the above-mentioned alterated or deposited layer is removed to thereby cause a non-alterated portion of an organic film pattern to appear;

(C) a part of a non-alterated portion of an organic film pattern is removed;

(D) the above-mentioned alterated or deposited layer existing on the fused/deformed organic film pattern or existing around the fused/deformed organic film pattern is selectively removed;

(E) the above-mentioned alterated or deposited layer existing on the fused/deformed organic film pattern or existing around the fused/deformed organic film pattern is selectively removed to thereby cause a non-alterated portion of an organic film pattern to appear;

(F) the above-mentioned alterated or deposited layer existing on the fused/deformed organic film pattern or existing around the fused/deformed organic film pattern is at least removed, and further, a part of the fused/deformed organic film pattern is removed; and

(G) the above-mentioned alterated or deposited layer existing on the fused/deformed organic film pattern or existing around the fused/deformed organic film pattern is selectively removed, and further, a part of the fused/deformed organic film pattern is removed.

In the above-mentioned ashing step, films formed on a substrate are etched through the use of at least one of plasma, ozone and ultraviolet rays.

A degree of alteration and a characteristic of an alterated layer depend highly on chemical solution to be used in wet-etching, whether dry-etching is isotropic or anisotropic, whether deposition exists on an organic film pattern, and gas used in dry-etching. Hence, difficulty in removing an alterated layer depends also on those. Thus, the removal step in the first to seventh aspects of the present invention is selected in accordance with a degree of alteration and a characteristic of an alterated layer.

The ashing step is carried out for removing only a surface of the alterated or deposited layer in the first to third removal steps, and the rest of the alterated or deposited layer is preferably removed by the first or second chemical solution step both of which is a wet step.

In comparison with the steps illustrated in FIGS. 2B, 3B and 4B in which the removal step is comprised only of an ashing step, the steps illustrated in FIGS. 2C, 3C and 4C make it possible to shorten a period of time for carrying out an ashing step to an organic film pattern, and further, to prevent a substrate and an organic film pattern from being damaged by an ashing step, providing an advantage that it is possible to remove an alterated or deposited layer firmly formed on an organic film pattern.

The first, second and third heating steps are carried out for the following purposes:

(A) water, acid solution or alkali solution penetrating an organic film pattern before the fusion/deformation step is carried out is removed; and

(B) when an adhesive force between an organic film pattern and a substrate or an underlying film is lowered, the adhesive force is enhanced.

Furthermore, a step of heating an organic film pattern to form the organic film patter, the first heating step, the second heating step, and the third heating step are carried out under the following conditions:

(A) the first heating step is carried out at a temperature lower than a temperature at which the second heating step is carried out;

(B) a heating step for forming the organic film pattern and the first heating step are carried out at a temperature lower than a temperature at which the second heating step is carried out;

(C) the second heating step is carried out at a temperature lower than a temperature at which the third heating step is carried out;

(D) a heating step for forming the organic film pattern, the first heating step, and the second heating step are carried out at a temperature lower than a temperature at which the third heating step is carried out;

(E) the first heating step is carried out at a temperature lower than a temperature at which the third heating step is carried out;

(F) a heating step for forming the organic film pattern and the first heating step are carried out at a temperature lower than a temperature at which the third heating step is carried out;

(G) a heating step for forming the organic film pattern is carried out at a temperature equal to or smaller than a temperature at which the organic film pattern is cross-linked;

(H) any heating step is carried out at a temperature in the range of 50 to 150 degrees centigrade both inclusive;

(I) any heating step is carried out at a temperature in the range of 100 to 130 degrees centigrade both inclusive; and

(J) a heating step for forming the organic film pattern, the first heating step, the second heating step, and the third heating step are carried out for 60 to 300 seconds both inclusive.

The above-mentioned steps (A) to (F) are carried out for removing an organic film pattern after carrying out the heating step by means of a developing function of the organic film pattern (for instance, when an organic film pattern is comprised of a photosensitive organic film). The above-mentioned steps (G) to (I) show examples of a temperature for keeping an organic film pattern to have a developing function, and further for enabling an organic film pattern to be well separated from a substrate. The above-mentioned step (J) shows an example of a period of time for carrying out the heating step taking into consideration a yield when a substrate is processed one by one.

Examples of the above-mentioned fusion/deformation step are listed hereinbelow:

(A) a step of enlarging an area of the organic film pattern;

(B) a step of unifying organic film patterns disposed adjacent to each other, into a single pattern;

(C) a step of planarizing an organic film pattern;

(D) a step of deforming an organic film pattern such that the organic film pattern is turned into an electrically insulating film covering a circuit pattern formed on a substrate; and

(E) a step of deforming an organic film pattern by causing the organic film pattern to make contact with organic solvent to thereby cause fusion reflow.

As the above-mentioned organic solvent, there is used organic solvent containing at least one of the followings (R indicates an alkyl group or a substitutional alkyl group, and Ar indicates a phenyl group or an aromatic ring other than a phenyl group):

Alcohol (R—OH);

Ether (R—O—R, Ar—O—R, Ar—O—Ar):

Ester,

Ketone; and

Glycol ether.

In order to cause the organic solvent to make contact with the organic film pattern (that is, in order to deform the organic film pattern by the fusion reflow), the organic film pattern may be exposed to vapors of the organic solvent, or the organic film pattern may be immersed into the organic solvent. The vapors of the organic solvent are provided, for instance, by heating the organic solvent, or by bubbling the organic solvent with inert gas (for instance, nitrogen (N₂) gas or argon (Ar) gas).

Thus, it is possible to fill a chamber with gas atmosphere of the organic solvent, and to cause the organic film pattern to make contact with the organic solvent by placing a substrate in the chamber.

When the organic film pattern is comprised of a photosensitive organic film, the following conditions may be very important to stably carry out particular steps (for instance, steps to be carried out by means of photosensitivity of an organic film pattern, or a developing function of chemical solution):

(A) after an organic film pattern was originally formed on a substrate, the organic film pattern is kept not exposed to light until the fusion/deformation step is carried out; and

(B) after an organic film pattern was originally formed on a substrate, the organic film pattern is kept not exposed to light until a step of exposing the organic film pattern to light or a step of exposing the organic film pattern to light through a lower surface of the organic film pattern is carried out.

The above-mentioned conditions are required because, by keeping the organic film pattern not exposed to light, it would be possible to advantageously carry out a step of exposing an organic film pattern to light, a step of exposing an organic film pattern to light through a lower surface of the organic film pattern, and a step of additionally exposing an organic film pattern to light, ensuring that the development step can be advantageously carried out.

The above-mentioned step of additionally exposing an organic film pattern to light is comprised of a step of exposing an organic film pattern to light before or immediately before carrying out at least one of the first and second chemical solution steps.

The above-mentioned step of exposing an organic film pattern to light through a lower surface of the organic film pattern is carried out between the fusion/deformation step and the third removal step or between the fusion/deformation step and the second chemical solution step. The above-mentioned step of exposing an organic film pattern to light through a lower surface of the organic film pattern makes it possible to selectively remove an unnecessary portion of an organic film pattern (for instance, a resist pattern) having an area having been increased due to the fusion reflow caused by the fusion/deformation step.

For instance, when an organic film pattern formed above a drain is to be fused to reflow, by exposing the organic film pattern to light through a lower surface thereof, a first portion of the fused/deformed organic film pattern hidden by a gate and a drain is not exposed to light, but a second portion of the fused/deformed organic film pattern not hidden a gate and a drain (that is, a second portion has a part hidden by a gate and a drain). Due to the difference between the above-mentioned first and second portions, it would be possible to remove an organic film pattern by the development step.

Namely, it is possible to carry out the development step for selectively removing a portion of an organic film pattern in the above-mentioned second chemical solution step as the third removal step, by using chemical solution having a function of developing the organic film pattern.

It would be possible to effectively remove an unnecessary portion of the fused/deformed organic film pattern by exposing the original organic film pattern to light with a half-tone mask in advance or by carrying out the light-exposure step during the development step.

For instance, an organic film pattern (which will be exposed to light with an ordinary mask or with a half-tone mask) used for forming a drain is kept not exposed to light until the above-mentioned step of exposing the organic film pattern to light through a lower surface thereof is carried out. Then, the step of exposing the organic film pattern to light through a lower surface thereof is applied to the organic film pattern, and then, the organic film pattern is developed in the second chemical solution step as the third removal step through the use of chemical solution having a function of developing the organic film pattern. By optimizing a period of time for carrying out the second chemical solution step (step of developing the organic film pattern through the use of chemical solution having a function of developing the organic film pattern), it is possible to pattern the fused/deformed organic film pattern only in a drain even after the fusion reflow. It is preferable that a period of time for developing the organic film pattern is minimized enough to completely remove the organic film pattern.

The above-mentioned step of exposing an organic film pattern to light or the above-mentioned step of exposing an organic film pattern to light through a lower surface of the organic film pattern can be carried out (a) with a photomask, (b) without a photomask, or (c) with a photomask having a pattern other than a minute pattern (equal to or smaller than 1 mm).

The above-mentioned step of exposing an organic film pattern to light may be comprised of (A) a step of ordinarily exposing an organic film pattern to light, (B) a step of exposing an organic film pattern to light only in an area associated with a predetermined area of a substrate, (C) a step of exposing an organic film pattern to light at a time only in the above-mentioned area, (D) a step of scanning the above-mentioned area with spot-light, (E) the above-mentioned area is equal to or greater than 1/10 of an area of a substrate, and (F) an organic film pattern is exposed to ultra-violet rays, fluorescence, or natural light, singly or in combination.

The above-mentioned step (A) is applied to a photosensitive organic film pattern through the use of chemical solution having a function of developing the organic film pattern, in order to newly form a pattern. The above-mentioned step (B) makes it possible to cause a portion or portions of a substrate to be sufficiently exposed to light, even if there is irregularity in exposure of the substrate to light. Namely, the step (B) can substantially overcome such irregularity, ensuring uniformity in a development step to be later carried out.

The above-mentioned first or second chemical solution step may be comprised of any one of the following steps:

(A) a step of developing an organic film pattern through the use of chemical solution having a function of developing the organic film pattern;

(B) a step of developing an organic film pattern through the use of chemical solution having a function of developing at least the organic film pattern;

(C) a N-th step of developing an organic film pattern, wherein N indicates an integer equal to or greater than two;

(D) a chemical solution step of applying chemical solution not having a function of developing an organic film pattern, but having a fusing an organic film pattern for removal, to the organic film pattern; and

(E) a chemical solution step of applying chemical solution for removal to an alterated or deposited layer formed on a surface of an organic film pattern.

As chemical solution for developing an organic film pattern, any one or more of the following chemical solution may be used.

(1) chemical solution obtained by diluting separating agent;

(2) organic or inorganic alkaline aqueous solution;

(3) alkaline aqueous solution containing TMAH (tetramethyl ammonium hydroxide) as a principal constituent;

(4) alkaline aqueous solution containing at least one of NaOH or CaOH;

(5) chemical solution containing at least acid;

(6) chemical solution containing at least organic solvent;

(7) chemical solution containing at least alkaline;

(8) chemical solution defined in (5), containing at least amine;

(9) chemical solution containing at least organic solvent and amine;

(10) chemical solution defined in (7), containing at least amine and water;

(11) chemical solution containing at least alkaline and amine;

(12) chemical solution defined in (8) to (11), containing, as amine, at least one of monoethyl amine, diethyl amine, triethyl amine, monoisopyl amine, diisopyl amine, triisoply amine, monobutyl amine, dibutyl amine, tributyl amine, hydroxylamine, diethylhydroxylamine, diethylhydroxylamine anhydride, pyridine, and picoline;

(13) chemical solution defined in (8) to (12), containing amine in the range of 0.01 to 30 weight % both inclusive;

(14) chemical solution defined in (8) to (12), containing amine in the range of 0.05 to 10 weight % both inclusive;

(15) chemical solution defined in (8) to (12), containing amine in the range of 0.05 to 5.0 weight % both inclusive;

(16) chemical solution containing anti-corrosive;

An organic film pattern originally formed on a substrate may have portions having at least two thicknesses. The originally formed organic film pattern is processed for one of the following purposes:

(A) by applying at least one of the first, second and third removal steps, a portion having a small thickness is selectively further thinned; and

(B) by applying at least one of the first, second and third removal steps, a portion having a small thickness is selectively removed.

A step of patterning an underlying film disposed beneath an organic film pattern may be carried out before or after or during an organic film pattern is processed. The step of patterning the underlying film is carried out, for instance, in one of the following steps:

(A) a step of patterning the underlying film disposed beneath the organic film pattern through the use of the organic film pattern as a mask before carrying out the fusion/deformation step;

(B) a step of patterning the underlying film disposed beneath the organic film pattern through the use of the organic film pattern as a mask before carrying out the fusion/deformation step, the first removal step or the first heating step;

(C) a step of patterning the underlying film disposed beneath the organic film pattern through the use of the organic film pattern as a mask before carrying out the third removal step, the second heating step or the third heating step;

(D) a step of patterning the underlying film disposed beneath the organic film pattern through the use of the organic film pattern as a mask before the organic film pattern is processed; and

(E) a step of patterning the underlying film disposed beneath the organic film pattern through the use of the organic film pattern as a mask after the organic film pattern has been processed.

The above-mentioned steps (A) to (E) may be carried out once or a plurality of times for patterning the underlying film.

The underlying film is processed for the following purposes:

(A) the underlying film is processed to be tapered or step-liked; and

(B) the underlying film is comprised of a plurality of films, and any one or more of the films is(are) patterned to have different patterns from others by processing the underlying film.

In the explanation made above, the present invention is applied to a method of processing a substrate such as a semiconductor substrate or a liquid crystal substrate. It should be noted that the present invention may be applied to a method of fabricating a device including a substrate, a method of fabricating a display device, a method of fabricating a semiconductor device, a method of fabricating a liquid crystal display device, a method of fabricating an EL display device, a method of fabricating a field emission display device, or a method of fabricating a plasma display device.

In the explanation made above, the present invention is applied to a substrate. It should be noted that the present invention may be applied to a method of fabricating a liquid crystal display device (a vertical electric field type liquid crystal display device, a horizontal electric field type liquid crystal display device, a light-transmission type liquid crystal display device, a light-reflection type liquid crystal display device, and a half-transmission type liquid crystal display device), and a display device such as an EL display device, or a method of fabricating other semiconductor devices.

The advantages obtained by the aforementioned present invention will be described hereinbelow.

A method of processing an organic film pattern formed on a substrate, in accordance with the present invention, includes, in sequence of, a fusion/deformation step of fusing and thereby deforming the organic film pattern, and a third removal step of removing at least a part of the fused and deformed organic film pattern.

The method in accordance with the present invention may include additionally various heating steps and various removal steps (a removal step of removing an alterated or deposited layer formed on a surface of an organic film pattern, or a removal step of removing at least a part of an organic film pattern).

An organic film pattern is enlarged in an area due the fusion/deformation step. The third removal step of removing at least a part of the fused and deformed organic film pattern reduces an area of the thus enlarged organic film pattern. Thus, it is possible to enhance controllability for patterning an organic film pattern into a desired pattern or a desired size.

The fusion/deformation step (specifically, a gas atmosphere step) was carried out also in the conventional method. The fusion/deformation step causes an organic film pattern to deform in the range of 5 to 20 micrometers (it is possible to deform an organic film pattern by 100 micrometers or more).

However, since an organic film pattern is much deformed, if the organic film pattern is required to be accurately patterned, it would be necessary to accurately control the deformation of the organic film pattern.

In order to reduce a number of photolithography steps, there may be used an organic film pattern (specifically, a resist pattern) for forming a source and a drain in a channel. The fusion/deformation step is used for deforming two separate portions of the resist pattern located in the vicinity of a channel, corresponding to the source and drain, thereby unifying the separate two portions to each other.

It is necessary to cause much “chemical solution fusion reflow” in order to stably unify the separate two portions to each other. However, if “chemical solution fusion reflow” is carried out so much, a resist pattern associated with portions other than a channel, such as wirings, would be much fused and deformed.

Accordingly, it was necessary in the conventional method to design a resist pattern to have two portions having different thicknesses from each other, and to remove a thinner portion of the resist pattern before carrying out the fusion/deformation step.

However, since an organic film pattern had an increased area due to the fusion/deformation step, it was necessary to accurately control a period of time for carrying out the fusion/deformation step to thereby control accurately the deformation of an organic film pattern, in order to prevent an area of the organic film pattern from increasing.

In contrast, though the method in accordance with the present invention includes the fusion/deformation step (specifically, a gas atmosphere step), the method in accordance with the present invention further includes a step of removing an unnecessary portion of the organic film pattern (for instance, a resist pattern) having an increased area due to the fusion/deformation reflow.

The step of removing the above-mentioned unnecessary portion of the organic film pattern may be comprised of an ashing step and a chemical solution step (using chemical solution having a function of developing an organic film pattern or a function of separating an organic film pattern) singly or in combination.

Specifically, the method of processing an organic film pattern formed on a substrate, in accordance with the present invention, includes a fusion/deformation step of fusing and thereby deforming the organic film pattern, and a removal step of removing at least a part of the fused and deformed organic film pattern.

A step of removing an alterated layer or a deposited layer formed on a surface of an organic film pattern may be carried out before the fusion/deformation step, if necessary.

Specifically, in the method in accordance with the present invention, after the fusion/deformation step has been carried out for fusing and thereby deforming an organic film pattern formed on a substrate, an unnecessary portion of the organic film pattern or a portion of the organic film pattern having an area having increased more than necessity is at least partially removed by various removal steps (defined in “third removal step” in claims).

In the conventional method, an area of an organic film pattern is only increased due to the fusion/deformation reflow, and an increasing rate is controlled by controlling a period of time during which the fusion/deformation reflow is carried out, for instance. In contrast, the present invention makes it possible to control an area of an organic film pattern in opposite ways. That is, the present invention provides the second control to an area of an organic film pattern by removing or contracting the organic film pattern after the fusion/deformation reflow was carried out, ensuring that the deformation of an organic film pattern can be accurately controlled.

In order to reduce a number of photolithography steps in the conventional method, there was used an organic film pattern (specifically, a resist pattern) for forming a source and a drain in a channel. The fusion/deformation step was used for deforming two separate portions of the resist pattern located in the vicinity of a channel, corresponding to the source and drain, thereby unifying the separate two portions to each other.

However, if the chemical solution fusion reflow caused by the fusion/deformation step is small, it was not possible to unify the separate two portions of an organic film pattern to each other, but there is less generated a portion of an organic film pattern having an area increased more than necessity. If the chemical solution fusion reflow caused by the fusion/deformation step is large, there was much generated a portion of an organic film pattern having an area increased more than necessity, but it is possible to unify the separate two portions of an organic film pattern to each other.

In contrast, when the method in accordance with the present invention is used for reducing a number of photolithography steps, the chemical solution reflow is caused sufficiently large due to the fusion/deformation step, and then, a deformed portion of the organic film pattern is removed or contracted in area, thereby the deformed portion of the organic film pattern would have a desired area. Thus, the method in accordance with the present invention provides only the merits in the conventional method.

In the explanation made above, the present invention is applied to a substrate. It should be noted that the present invention may be applied to a method of fabricating a liquid crystal display device (a vertical electric field type liquid crystal display device, a horizontal electric field type liquid crystal display device, a light-transmission type liquid crystal display device, a light-reflection type liquid crystal display device, and a half-transmission type liquid crystal display device), and a display device such as an EL display device, or a method of fabricating other semiconductor devices.

The above and other objects and advantageous features of the present invention will be made apparent from the following description made with reference to the accompanying drawings, in which like reference characters designate the same or similar parts throughout the drawings.

### BRIEF DESCRIPTION OF THE DRAWINGS

FIG. 1A is a flow-chart showing steps to be carried out in the method in accordance with the first embodiment of the present invention.

FIG. 1B is a flow-chart showing steps to be carried out in the method in accordance with the second embodiment of the present invention.

FIG. 1C is a flow-chart showing steps to be carried out in the method in accordance with the third embodiment of the present invention.

FIG. 2A is a flowchart showing steps to be carried out in a first example of the first removal step.

FIG. 2B is a flowchart showing steps to be carried out in a second example of the first removal step.

FIG. 2C is a flowchart showing, steps to be carried out in a third example of the first removal step.

FIG. 3A is a flowchart showing steps to be carried out in a first example of the second removal step.

FIG. 3B is a flowchart showing steps to be carried out in a second example of the second removal step.

FIG. 3C is a flowchart showing steps to be carried out in a third example of the second removal step.

FIG. 4A is a flowchart showing steps to be carried out in a first example of the third removal step.

FIG. 4B is a flowchart showing steps to be carried out in a second example of the third removal step.

FIG. 4C is a flowchart showing steps to be carried out in a third example of the third removal step.

FIG. 4D is a flowchart showing steps to be carried out in a fourth example of the third removal step.

FIG. 5 is a planar view of an example of an apparatus for processing a substrate.

FIG. 6 is a planar view of another example of an apparatus for processing a substrate.

FIG. 7 is a schematic showing candidates of process units to be equipped in an apparatus for processing a substrate.

FIG. 8 is a cross-sectional view of an example of a unit for applying chemical solution to an organic film pattern.

FIG. 9 is a cross-sectional view of an example of a unit for applying gas atmosphere to an organic film pattern.

FIG. 10 is a cross-sectional view of another example of a unit for applying gas atmosphere to an organic film pattern.

FIG. 11A shows steps to be carried out in the first conventional method.

FIG. 11B shows steps to be carried out in the second conventional method.

FIG. 11C shows steps to be carried out in the third conventional method.

FIG. 12 illustrates a degree of alteration of an alterated layer in dependence on causes by which the alterated layer is formed.

FIG. 13 is a graph showing relation between a concentration of amine in chemical solution and a removal rate.

FIG. 14 illustrates variation of an alterated layer to which only a step of applying chemical solution is applied.

FIG. 15 illustrates variation of an alterated layer to which an ashing step and a step of applying chemical solution are applied in this order.

FIG. 16 illustrates a difference with respect to how an organic film pattern is processed in a fusion/deformation step.

FIG. 17A is a graph showing relation between a concentration of amine in chemical solution and a removal rate, in association with whether an organic film pattern is alterated or not.

FIGS. 18A, 18B, 18C, 18D, 18E, 18F and 18G are plan and cross-sectional views of a thin film transistor (TFT) device in a conventional method of fabricating a TFT substrate, including a conventional fusion/deformation/reflow process.

FIGS. 19A, 19B, 19C, 19D, 19E, 19F and 19G are plan and cross-sectional views of a thin film transistor (TFT) device in a method of fabricating a TFT substrate, in accordance with the fourth embodiment of the present invention.

FIGS. 20A, 20B, 20C, 20D, 20E, 20F and 20G are plan and cross-sectional views of a thin film transistor (TFT) device in a method of fabricating a TFT substrate, in accordance with the fifth embodiment of the present invention.

### DESCRIPTION OF THE PREFERRED EMBODIMENTS

Preferred embodiments in accordance with the present invention will be explained hereinbelow with reference to drawings.

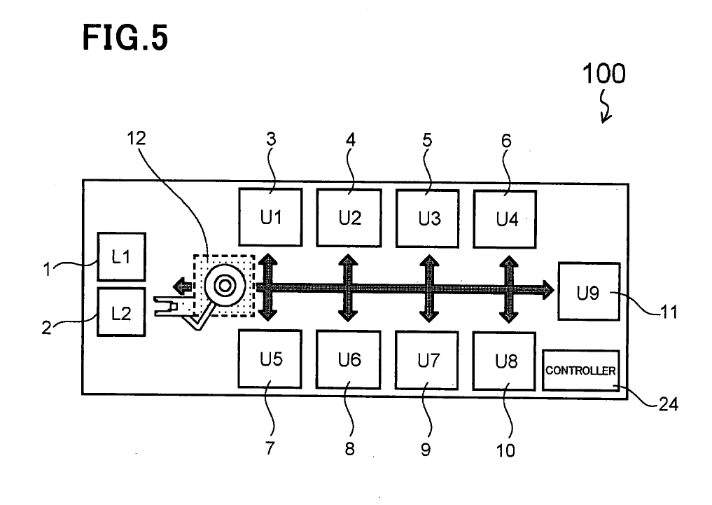

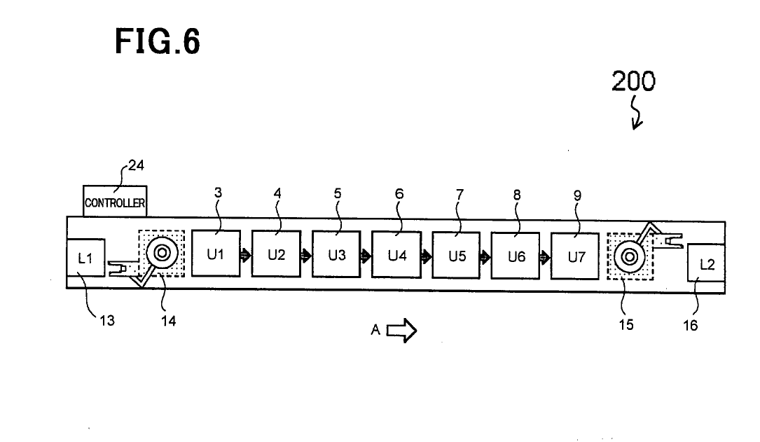

The method in accordance with an embodiment of the present invention is carried out in an apparatus 100 for processing a substrate, illustrated in FIG. 5 or an apparatus 200 for processing a substrate, illustrated in FIG. 6, for instance.

The apparatus 100 illustrated in FIG. 5 includes a plurality of process units, and an order in which the process units are operated is variable.

The apparatus 200 illustrated in FIG. 6 includes a plurality of process units, and an order in which the process units are operated is fixed.

The apparatuses 100 and 200 are designed to be able to selectively have later-mentioned process units to apply various steps to a substrate.

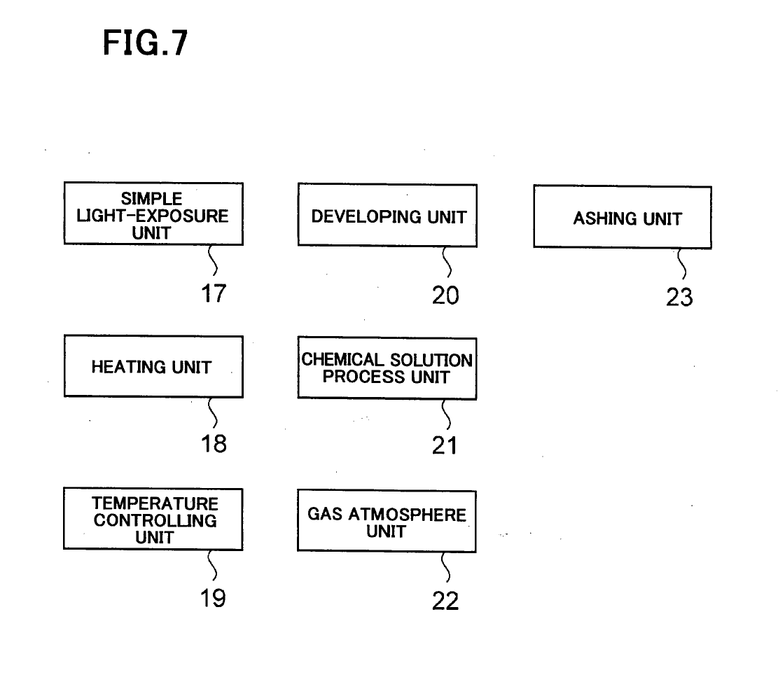

For instance, as illustrated in FIG. 7, the apparatuses 100 and 200 may include seven process units, specifically, a simple light-exposure unit 17 for exposing an organic film pattern to light, a heating unit 18 for heating an organic film pattern, a temperature controlling unit 19 for controlling a temperature of an organic film pattern, a developing unit 20 for developing an organic film pattern, a chemical solution process unit 21 for applying chemical to an organic film pattern, a gas atmosphere unit 22 for applying gas atmosphere to an organic film pattern, and an ashing unit 23 for applying ashing to an organic film pattern.

The apparatus 100 or 200 is comprised of a substrate carrier (a substrate-carrier robot), a cassette station in which a cassette is placed, and one or more process units selected among the above-mentioned seven process units.

In the light-exposure unit 17 for exposing an organic film pattern to light, an organic film pattern formed on a substrate is exposed to light. For instance, the light-exposure step of can be carried out (a) with a photomask, (b) without a photomask, or (c) with a photomask having a pattern other than a minute pattern (equal to or smaller than 1 mm).

The step of exposing an organic film pattern to light may be comprised of (A) a step of ordinarily exposing an organic film pattern to light, (B) a step of exposing an organic film pattern to light only in an area associated with a predetermined area of a substrate, (C) a step of exposing an organic film pattern to light at a time only in the above-mentioned area, (D) a step of scanning the above-mentioned area with spot-light, (E) the above-mentioned area is equal to or greater than 1/10 of an area of a substrate, and (F) an organic film pattern is exposed to ultra-violet rays, fluorescence, or natural light, singly or in combination. The light-exposure unit 17 exposes an organic film pattern to light in accordance with the above-mentioned steps singly or in combination.

The above-mentioned step (A) is applied to a photosensitive organic film pattern through the use of chemical solution having a function of developing the organic film pattern, in order to newly form a pattern. The above-mentioned step (B) makes it possible to cause a portion or portions of a substrate to be sufficiently exposed to light, even if there is irregularity in exposure of the substrate to light. Namely, the step (B) can substantially overcome such irregularity, ensuring uniformity in a development step to be later carried out.

In the heating unit 18 for heating an organic film pattern, a substrate or an organic film pattern is heated or baked in the range of 80 to 180 degrees centigrade or 100 to 150 degrees centigrade, for instance.

The heating unit 18 is comprised of a stage on which a substrate is held horizontally, and a chamber in which the stage is arranged.

The temperature controlling unit 19 controls a temperature of an organic film pattern and/or a substrate. For instance, the temperature controlling unit 19 keeps an organic film pattern and/or a substrate in the range of 10 to 50 degrees centigrade or 10 to 80 degrees centigrade, for instance.

The temperature controlling unit 19 is comprised of a stage on which a substrate is held horizontally, and a chamber in which the stage is arranged.

The heating unit 18 and the temperature controlling unit 19 can control a broad range of a temperature. Hence, if one of them can control a temperature from a high temperature to a low temperature (for instance, 10 to 180 degrees centigrade), it can carry out the temperature control in place of the other by changing a range of a temperature to be controlled.

In the chemical solution process unit 21, chemical solution is applied to an organic film pattern or a substrate.

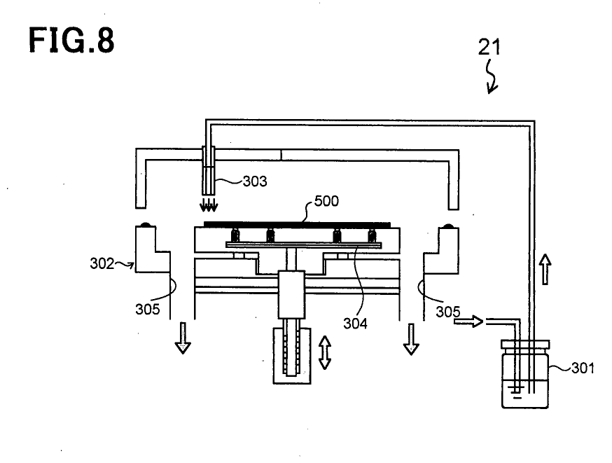

As illustrated in FIG. 8, the chemical solution process unit 21 is comprised of, for instance, a chemical tank 301 in which chemical solution is accumulated, and a chamber 302 in which a substrate 500 is arranged.

The chamber 302 includes a movable nozzle 303 for supplying chemical solution transported from the chemical tank 301, onto the substrate 500, a stage 304 on which the substrate 500 is held substantially horizontally, and an exhaust outlet 305 through which exhaust liquid and gas leave the chamber 302.

In the chemical solution process unit 21, chemical solution accumulated in the chemical tank 301 can be supplied to the substrate 500 through the movable nozzle 303 by compressing nitrogen gas into the chemical tank 301. The movable nozzle 303 is movable horizontally. The stage 304 includes a plurality of standing pins for supporting the substrate 500 at a lower surface thereof.

The chemical solution process unit 21 may be designed to be of a dry type in which chemical is vaporized, and the thus vaporized chemical is supplied onto the substrate 500.

For instance, chemical solution used in the chemical solution process unit 21 (chemical solution accumulated in the chemical tank 301) contains at least one of acid solution, organic solvent and alkaline solution.

In the developing process unit 20 for developing an organic film pattern, an organic film pattern is developed or overdeveloped.

For instance, the developing process unit 20 may be designed to have the same structure as that of the chemical solution process unit 21 except that developing agent is accumulated in the chemical tank 301.

In the gas atmosphere unit 22, there is carried out a gas atmosphere step in which various gases are applied to an organic film pattern to thereby fuse and deform the organic film pattern (fusion/deformation step).

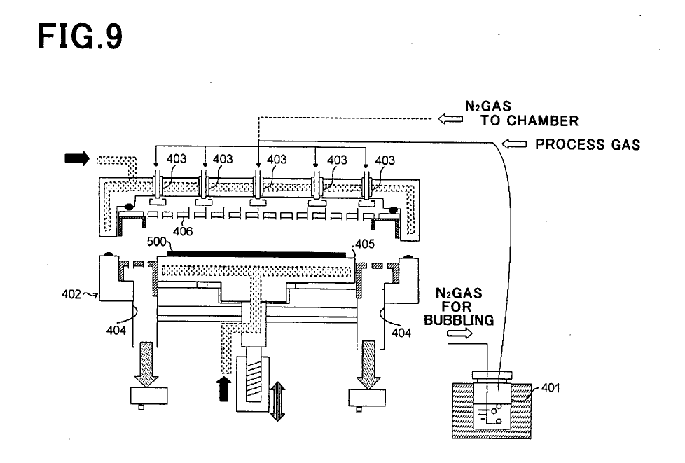

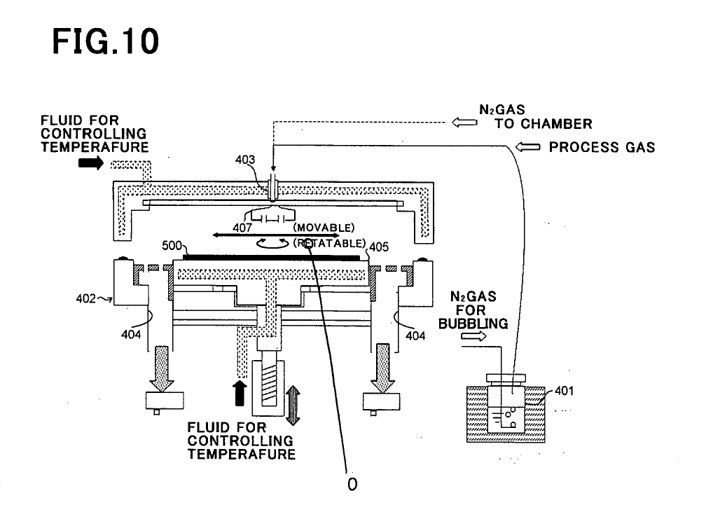

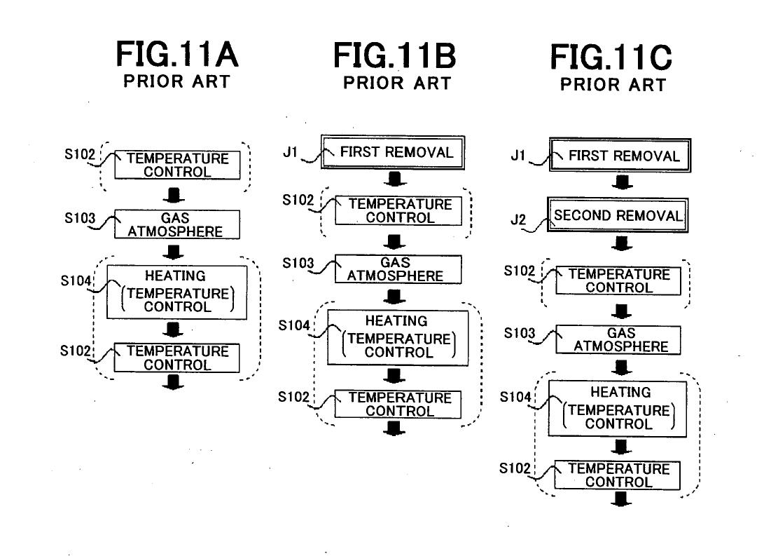

As illustrated in FIGS. 9 and 10, the sixth gas atmosphere unit 22 may be comprised of a container 401 in which a gas is produced by bubbling, and a chamber 402 in which a substrate 500 is arranged.

The chamber 402 includes a gas inlet 403 through which a gas is introduced into the chamber 402 from the container 401, an exhaust outlet 404 through which gas is exhausted from the chamber 402, a stage 405 for substantially horizontally holding the substrate 500, and a temperature controller for keeping the chamber 402 and the container 401 at a predetermined temperature.

The chamber 402 may include a plurality of gas inlets 403 located at different sites from one another, and a gas distribution plate 406 having a plurality of apertures formed therethrough for dispersing and distributing gas onto the substrate 500 supported on the stage 405, as illustrated in FIG. 9. As an alternative, the chamber 402 may include a single gas inlet 403, and a distributor 407 distributing gas supplied through the gas inlet 403, by rotation, as illustrated in FIG. 10.

In the gas atmosphere unit 22, liquid (for instance, organic solvent) accumulated in the container 401 is bubbled by introducing nitrogen gas thereinto, gas produced by bubbling the liquid is introduced into the chamber 402 through the gas inlet 403, and the substrate 500 is exposed to the gas.

In the ashing unit 23, an organic film pattern formed on the substrate 500 is etched by plasma (oxygen plasma or oxygen/fluorine plasma), optical energy of a light having a short wavelength, such as ultra-violet ray, ozone-processing using optical energy or heat, or other steps.

As illustrated in FIG. 5, the apparatus 100 is comprised of a first cassette station 1 in which a cassette L1 in which a substrate (for instance, a LCD substrate or a semiconductor wafer) is accommodated is placed, a second cassette station 2 in which a cassette L2 similar to the cassette L1 is placed, process-unit arrangement areas 3 to 11 in each of which process units U1 to U9 is arranged, respectively, a robot 12 for transporting a substrate between the first and second cassette stations 1 and 2 and the process units U1 to U9, and a controller 24 for controlling the robot 12 to transport of a substrate and the process units U1 to U9 to carry out various processes.

For instance, substrates not yet processed by the apparatus 100 are accommodated in the cassette L1, and substrates having been processed by the apparatus 100 are accommodated in the cassette L2.

Any one of the seven process units illustrated in FIG. 7 is selected as each of the process units U1 to U9 to be arranged in the process-unit arrangement areas 3 to 11.

The number of process units is determined in accordance with a kind of process and a capacity of a process unit. Accordingly, no process unit may be arranged in any one or more of the process-units arrangement areas 3 to 11.

For instance, the controller 24 is comprised of a central processing unit (CPU) and at least one memory. The memory stores a control program used for controlling an operation of the process units U1 to U9 and the robot 12. The central processing unit controls the process units U1 to U9 and the robot 12 in accordance with the control program.

The controller 24 selects a program in accordance with a process to be carried out in each of the process units U1 to U9 and the robot 12, and executes the selected program to thereby control operation of the process units U1 to U9 and the robot 12.

Specifically, the controller 24 controls an order of transportation of a substrate carried out by the robot 12, in accordance with data about an order of processes, to thereby take a substrate out of the first and second cassette station 1 and 2 and the process units U1 to U9, and introduces a substrate into them in accordance with a predetermined order.

Furthermore, the controller 24 controls an operation of the process units U1 to U9 in accordance with data about process conditions.

As illustrated in FIG. 6, the apparatus 200 is comprised of a first cassette station 13 in which a cassette L1 is placed, a second cassette station 16 in which a cassette L2 is placed, process-unit arrangement areas 3 to 9 in each of which process units U1 to U7 is arranged, respectively, a first robot 14 for transporting a substrate between the cassette L1 and the process unit U1, a second robot 15 for transporting a substrate between the process unit U7 between the cassette L2, and a controller 24 for controlling operation of the first and second robots 14 and 15 to transport of a substrate and the process units U1 to U7 to carry out various processes.

In the apparatus 200, an order of processes carried out in the process units U1 to U7 is fixed. Specifically, processes are continuously carried out from a process unit located upstream, that is, in a direction indicated with an arrow A in FIG. 6.

Any one of the seven process units illustrated in FIG. 7 is selected as each of the process units U1 to U7 to be arranged in the process-unit arrangement areas 3 to 9. The number of process units is determined in accordance with a kind of process and a capacity of a process unit. Accordingly, no process unit may be arranged in any one or more of the process-units arrangement areas 3 to 9.

The controller 24 of the apparatus 200 controls the robot 12 such that an order of carrying a substrate is determined in accordance with a fixed order of processing a substrate. Specifically, the controller 24 of the apparatus 200 controls the robot 12 such that a substrate is taken out of or carried into the first and second cassette stations 1 and 2 and the process units U1 to U7 in a predetermined order.

Furthermore, the controller 24 of the apparatus 200 carries out processes in the process units U1 to U7 in a predetermined order determined in accordance with fixedly determined process conditions in a method of processing a substrate.

Though the apparatuses 100 and 200 illustrated in FIGS. 5 and 6 are designed to include nine and seven process units, respectively, the number of process units to be included in the apparatuses 100 and 200 may be determined in accordance with a kind of a process, a capacity of a process unit, costs and so on.

Furthermore, though the apparatuses 100 and 200 are designed to include two cassettes L1 and L2, the number of cassettes may be determined in accordance with a required capacity, costs and so on.

The apparatuses 100 and 200 may include a process unit(s) other than the seven process units illustrated in FIG. 7. For instance, the apparatuses 100 and 200 may include a process unit for exposing a substrate to a light for making a minute pattern, a process unit for wet- or dry-etching a substrate, a process unit for coating a resist film onto a substrate, a process unit for strengthening an adhesion force between a substrate and an organic film pattern, or a process unit for washing a substrate (dry washing through ultra-violet ray or plasma, and wet washing through a washing agent).

If the apparatuses 100 and 200 include a process unit for wet-etching or dry-etching a substrate, it would be possible to pattern an underlying film (for instance, a surface of a substrate) with an organic film pattern being used as a mask.

The chemical solution process unit 21 may be used as a process unit for wet- or dry-etching a substrate, if the chemical solution process unit 21 includes chemical by which an underlying film can be etched, specifically, etchant containing acid or alkali.

In order to uniformize each of processes, the apparatuses 100 and 200 may include a plurality of common process units for applying common process to a substrate a plurality of times.

When the apparatuses 100 and 200 include a plurality of common process units for applying common process to a substrate a plurality of times, it is preferable that a substrate is processed in the common process units such that the substrate is directed in different directions from one another (for instance, oppositely) in the common process units. In such a case, the apparatuses 100 and 200 are preferably designed to have a function of directing a substrate differently in the process units, ensuring that a substrate is turned in different directions not manually, but automatically.

When the apparatuses 100 and 200 include a single certain process unit, it is preferable that a substrate is processed in the process unit a plurality of times with the substrate being directed in different directions from one another in each of the times.

For instance, it is preferable that a substrate is processed in a plurality of directions opposite to each other, in which case, the apparatuses 100 and 200 are preferably designed to have a function of processing a substrate in a certain process unit with the substrate being directed in different directions from one another in each of the times.

It is also preferable that a substrate is processed in a process unit in a first direction and further in a second direction different from the first direction, in which case, the apparatuses 100 and 200 are preferably designed to have a function of doing so.

Hereinbelow are explained preferred embodiments in accordance with the present invention.

### First Embodiment

Hereinbelow is explained the method of a processing a substrate, in accordance with the first embodiment of the present invention.

The method in accordance with the first embodiment of the present invention is carried out for the following purposes:

(a) when an underlying film (for instance, a substrate) is etched with an organic film pattern (for instance, a resist film) being used as a mask, the underlying film is etched to be tapered (for instance, see Japanese Patent Application Publication No. 2002-334830), or etched in a minute size (an organic film pattern is enlarged with respect to an area, or a contact hole is reduced with respect to a size to thereby reduce an etching size);

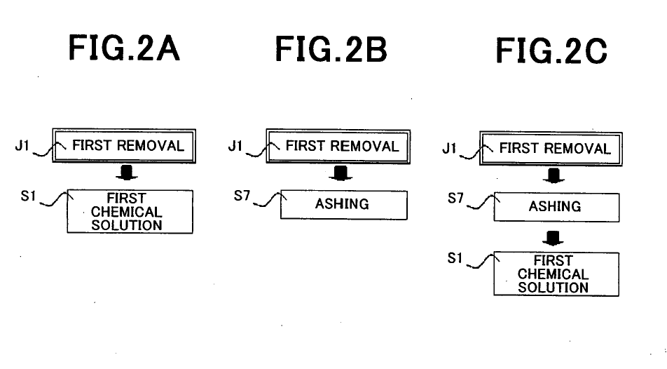

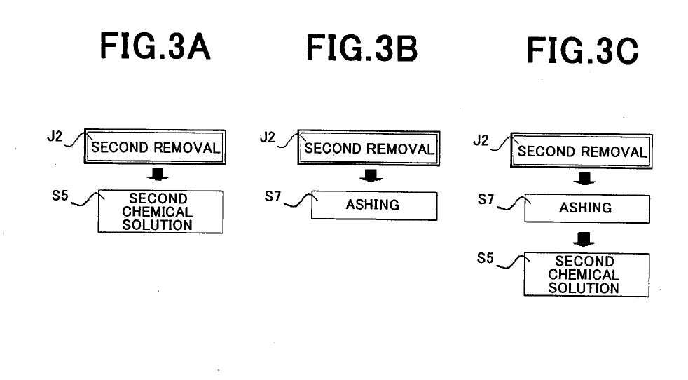

(b) when an underlying film (for instance, a substrate) is etched with an organic film pattern (for instance, a resist film) being used as a mask, the underlying film is etched into a two-layered structure, two patterns different from each other, or a combination of a separate pattern and combined patterns (for instance, see FIGS. 2 and 3 of the above-mentioned Japanese Patent Application Publication No. 2002-334830), by etching the underlying film prior to and subsequently to a fusion/deformation step; and

(c) when an organic film pattern is electrically insulating, the organic film pattern is deformed to cause the organic film pattern to act as an electrically insulating film covering a circuit pattern formed on a substrate.

The method in accordance with the first embodiment of the present invention provides steps of processing an organic film pattern for accomplishing the above-mentioned purposes (a) to (c).

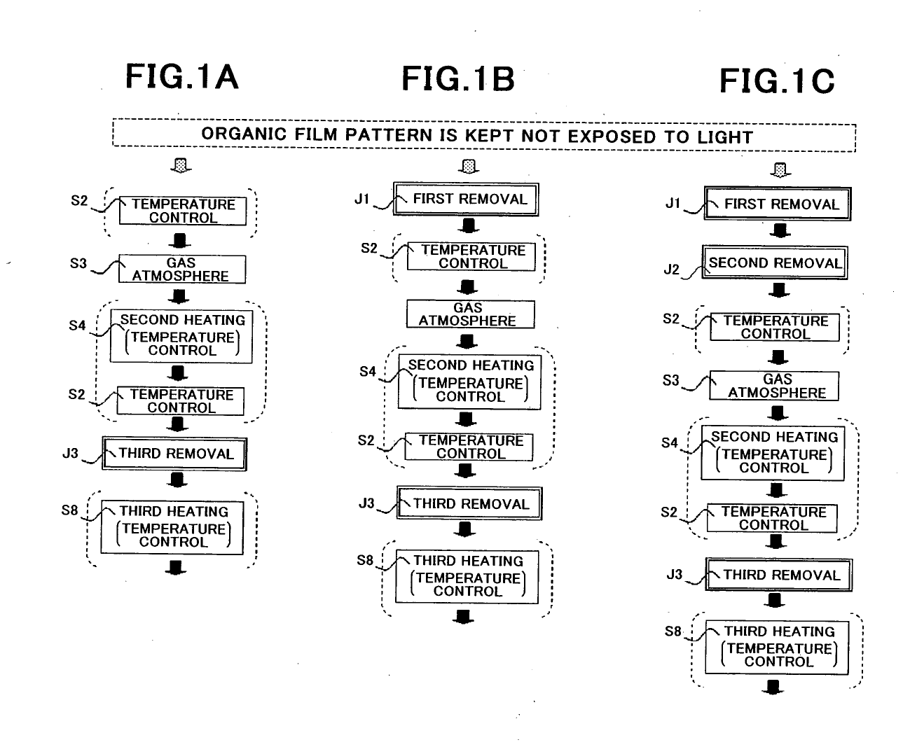

FIG. 1A is a flow-chart showing steps to be carried out in the method in accordance with the first embodiment of the present invention.

As illustrated in FIG. 1A, the method includes, in sequence of, a temperature-controlling step S2 of controlling a temperature of a substrate or an organic film pattern, a gas-atmosphere step S3 of exposing the organic film pattern to gas atmosphere, a second heating step S4 of heating the organic film pattern, a temperature-controlling step S2 of controlling a temperature of a substrate or the organic film pattern, a third removal step J3, and a third heating step S8.

The temperature-controlling step S2, the second heating step S4, and the third heating step S8 embraced with broken-line brackets in FIG. 1A may be omitted.

Furthermore, the second heating step S4, the third heating step S8, and the temperature-controlling step S2 may be carried out by changing a temperature range in a processing unit prepared for carrying out those steps.

The method in accordance with the first embodiment can have variants as follows.

### (Variant 1)

The method in accordance with the variant 1 includes, in sequence of, a gas-atmosphere step S3 of exposing the organic film pattern to gas atmosphere to thereby fuse and deform an organic film pattern, and a third removal step J3 of removing at least a part of the fused/deformed organic film pattern.

### (Variant 2)

The method in accordance with the variant 2 includes, in sequence of, a gas-atmosphere step S3 of exposing the organic film pattern to gas atmosphere to thereby fuse and deform an organic film pattern, a second heating step S4 of heating the fused/deformed organic film pattern, and a third removal step J3 of removing at least a part of the fused/deformed organic film pattern.

### (Variant 3)

The method in accordance with the variant 3 includes, in sequence of, a gas-atmosphere step S3 of exposing the organic film pattern to gas atmosphere to thereby fuse and deform an organic film pattern, a second heating step S4 of heating the fused/deformed organic film pattern, a third removal step J3 of removing at least a part of the fused/deformed organic film pattern, a third heating step S8 of heating the fused/deformed organic film pattern.

### (Variant 4)

The method in accordance with the variant 4 includes, in sequence of, a first heating step S9 of heating an organic film pattern, a gas-atmosphere step S3 of exposing the organic film pattern to gas atmosphere to thereby fuse and deform an organic film pattern, a second heating step S4 of heating the fused/deformed organic film pattern, a third removal step J3 of removing at least a part of the fused/deformed organic film pattern, a third heating step S8 of heating the fused/deformed organic film pattern.

The variants 1 to 4 may include a temperature controlling step of keeping a temperature of a substrate constant. The temperature controlling step is carried out immediately before the fusion/deformation step S3.

As explained above, the method in accordance with the first embodiment necessarily includes the gas-atmosphere step S3 and the third removal step J3, and other steps may be omitted, if necessary.

In the gas atmosphere step S3, a substrate is exposed in the gas atmosphere unit 22 to various gases (for instance, gas originated from organic solvent) to thereby carry out the fusion/deformation step in which an organic film pattern formed on a substrate is fused and thereby deformed.

For instance, the gas atmosphere step S3 is carried out in gas atmosphere originated from organic solvent.

In the embodiments or examples of the present invention mentioned hereinbelow, the fusion/deformation step is carried out as a gas atmosphere step in which the following organic solvents are used. Hence, the fusion/deformation step is treated as being identical to the gas atmosphere step S3 or as having the same function as the gas atmosphere step S3.

List 1 shows organic solvent to be preferably used in the gas atmosphere step S3.

### [List 1]

Alcohol (R—OH)

Alkoxy alcohol

Ether (R—O—R, Ar—O—R, Ar—O—Ar)

Ester

Keton

Glycol

Alkylene glycol

Glycol ether

In List 1, R indicates an alkyl group or a substitutional alkyl group, and Ar indicates a phenyl group or an aromatic ring other than a phenyl group.

List 2 shows specific organic solvent to be preferably used in the gas atmosphere step S3.

### [List 2]

CH₃OH, C₂H₅OH, CH₃(CH₂)XOH

Isopropyl alcohol (IPA)

Etoxy ethanol

Methoxy alcohol

Long-chain alkyl ester

Monoethanol amine (MEA)

Monoethyl amine

Diethyl amine

Triethyl amine

Monoisopropyl amine

Diisopropyl amine

Triisoproply amine

Monobutyl amine

Dibutyl amine

Tributyl amine

Hydroxylamine

Diethylhydroxylamine

Diethylhydroxylamine anhydride

pyridine

picolne

acetone

Acetyl acetone

Dioxane

Ethyl acetate

Buthyl acetate

Toluene

Methylethyl ketone (MEK)

Diethyl ketone

Dimethyl sulfoxide (DMSO)

Methylisobutyl ketone (MIBK)

Butyl carbitol

n-butylacetate (nBA)

Gammerbutyrolactone

Ethylcellosolve acetate (ECA)

Ethyl lactate

Pyruvate ethyl

2-heptanone

3-methoxybutyl acetate

Ethylene glycol

Propylene glycol

Buthylene glycol

Ethylene glycol monoethyl ether

Diethylene glycol monoethyl ether

Ethylene glycol monoethyl ether acetate

Ethylene glycol monomethyl ether

Ethylene glycol monomethyl ether acetate

Ethylene glycol mono-n-buthyl ether

Polyethylene glycol

Polypropylene glycol

Polybuthylene glycol

Polyethylene glycol monoethyl ether

Polydiethylene glycol monoethyl ether

Polyethylene glycol monoethyl ether acetate

Polyethylene glycol monomethyl ether

Polyethylene glycol monomethyl ether acetate

Polyethylene glycol mono-n-buthyl ether

Methyl-3-methoxypropionate (MMP)

Propylene glycol monomethyl ether (PGME)

Propylene glycol monomethyl ether acetate (PGMEA)

Propylene glycol monopropyl ether (PGP)

Propylene glycol monoethyl ether (PGEE)

Ethyl-3-ethoxypropionate (FEP)

Dipropylene glycol monoethyl ether

Tripropylene glycol monoethyl ether

Polypropylene glycol monoethyl ether

Propylene glycol monomethyl ether propionate

3-methoxymethyl propionate

3-ethoxymethyl propionate

N-methyl-2-pyrrolidone (NMP)

The step of applying gas atmosphere to a substrate through the use of gas produced from organic solvent is carried out, if an organic film pattern is fused when organic solvent percolates thereinto.

For instance, an organic film pattern is soluble in water, acid and alkali, the step of applying gas atmosphere to a substrate may be carried out through the use of gas produced from aqueous solution, acid solution and alkaline solution.

In the second heating step S4, a stage of the heating unit 18 is kept at a predetermined temperature (for instance, a temperature in the range of 80 to 180 degrees centigrade), and a substrate is placed on the stage for a predetermined period of time (for instance, 3 to 5 minutes). The second heating step makes it possible for gas used in the gas atmosphere step to deeply penetrate an organic film pattern, and further, to surely cause the fusion/deformation step to proceed. This means that conventional reflow caused by heating is additionally caused.

The heating reflow readily occurs, if organic solvent much penetrates the organic film pattern. In comparison with carrying out only heating reflow by heating, it is effective to cause the heating reflow in the second heating step S4.

Furthermore, the second heating step S4 puts the organic film pattern into a stable condition before the next step or the third removal step J3 is carried out.

In particular, when the third removal step J3 is comprised of the second chemical solution step in which a developing agent or chemical solution having a function of developing an organic film pattern is used, the second heating step S4 puts an organic film pattern into such a condition as the organic film pattern is pre-baked before the organic film pattern is developed, ensuring that a developing rate can be controlled.

Namely, when the third removal step is comprised of the second chemical solution step in which a developing agent or chemical solution having a function of developing an organic film pattern is used, a developing rate reduces as a temperature at which an organic film pattern is heated rises. Thus, it would be possible to control a degree or an amount of an organic film pattern to be partially removed, by controlling a period of time for carrying out the second heating step.

It should be noted that it is necessary to carry out the second heating step at a temperature below a temperature at which resin of which an organic film pattern (in particular, a resist film) is composed is cross-linked, and thus, a developing rate significantly reduces or an organic film pattern cannot be developed.

For an example of a temperature at which the second heating step is carried out, when an organic film pattern is comprised of a positive type photosensitive organic film, and contains novolak resin as a principal constituent, the second heating step is carried out preferably in the range of 50 to 150 degrees centigrade, and more preferably in the range of 100 to 130 degrees centigrade. By carrying out the second heating step in such a range of a temperature, it would be possible to accomplish a slow developing rate, and to control a removal rate of an organic film pattern, an amount of an organic film pattern to be removed, and a degree of removal of an organic film pattern.

If a temperature at which an organic film pattern is heated after the organic film pattern was formed and before the second heating step S4 is carried out is higher than a temperature at which the second heating step S4 is carried out, the temperature control resulted from the second heating step S4 would be meaningless. Accordingly a temperature at which an organic film pattern is heated before the second heating step S4 is carried out has to be equal or lower than a temperature at which the second heating step S4 is carried out.

In the third removal step J3, a part of an organic film pattern (for instance, a resist pattern) having an area having been increased more than necessity in the fusion/deformation reflow, among the organic film pattern having been fused and deformed in the gas atmosphere step S3, is removed.

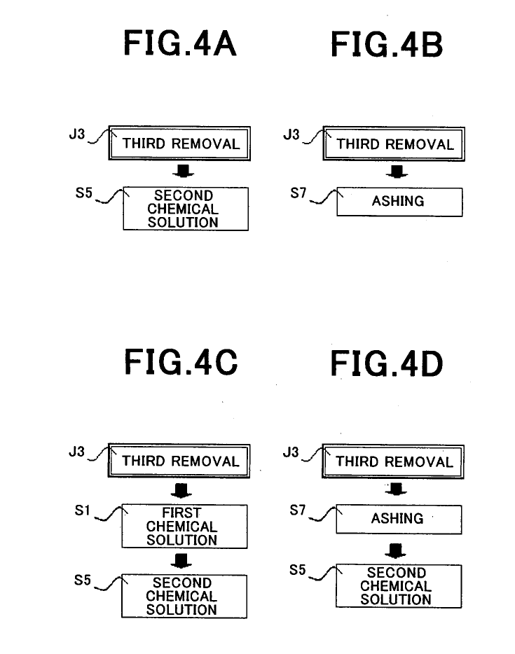

FIGS. 4A, 4B, 4C and 4D are flowcharts each showing a step or steps to be carried out in examples of the third removal step J3.

As illustrated in FIG. 4A, a first example of the third removal step J3 is comprised of the second chemical solution step S5 for applying chemical solution to an organic film pattern. There is used chemical solution having a function of developing an organic film pattern or a function of separating an organic film pattern from a substrate.

As illustrated in FIG. 4B, a second example of the third removal step J3 is comprised of the above-mentioned ashing step S7 for ashing an organic film-pattern.

As illustrated in FIG. 4C, a third example of the third removal step J3 is comprised of, in sequence of, the first chemical solution step S11 in which chemical solution having a function of removing at least an alterated layer or a deposited layer formed at a surface of an organic film pattern), and the second chemical solution step S5.

As illustrated in FIG. 4D, a fourth example of the third removal step J3 is comprised of, in sequence of, the ashing step S7, and the second chemical solution step S5.

In the ashing step, films formed on a substrate are etched with at least one of plasma, ozone and ultraviolet rays.

The removal step J3 may be carried out for the purpose of removing an alterated layer or a deposited layer formed at a surface of the organic film pattern.

The third removal step may be comprised of the first or second chemical solution step, in which case, each of the first, third and fourth examples of the third removal step is comprised of the following step:

The above-mentioned first or second chemical solution step may be comprised of any one of the following steps:

(A) a step of developing an organic film pattern through the use of chemical solution having a function of developing the organic film pattern;

(B) a step of developing an organic film pattern through the use of chemical solution having a function of developing at least the organic film pattern;

(C) a N-th step of developing an organic film pattern, wherein N indicates an integer equal to or greater than two;

(D) a chemical solution step of applying chemical solution not having a function of developing an organic film pattern, but having a fusing an organic film pattern for removal, to the organic film pattern; and

(E) a chemical solution step of applying chemical solution for removal to an alterated or deposited layer formed on a surface of an organic film pattern.

As chemical solution to be used in the first and second chemical solution steps, any one or more of the following chemical solution may be used.

(1) chemical solution obtained by diluting separating agent;

(2) organic or inorganic alkaline aqueous solution;

(3) alkaline aqueous solution containing TMAH (tetramethyl ammonium hydroxide) as a principal constituent;

(4) alkaline aqueous solution containing at least one of NaOH or CaOH;

(5) chemical solution containing at least acid;

(6) chemical solution containing at least organic solvent;

(7) chemical solution containing at least alkaline;

(8) chemical solution defined in (5), containing at least amine;

(9) chemical solution containing at least organic solvent and amine;

(10) chemical solution defined in (7), containing at least amine and water;

(11) chemical solution containing at least alkaline and amine;

(12) chemical solution defined in (8) to (11), containing, as amine, at least one of monoethyl amine, diethyl amine, triethyl amine, monoisopyl amine, diisopyl amine, triisoply amine, monobutyl amine, dibutyl amine, tributyl amine, hydroxylamine, diethylhydroxylamine, diethylhydroxylamine anhydride, pyridine, and picoline;

(13) chemical solution defined in (8) to (12), containing amine in the range of 0.01 to 30 weight % both inclusive;

(14) chemical solution defined in (8) to (12), containing amine in the range of 0.05 to 10 weight % both inclusive; (15) chemical solution defined in (8) to (12), containing amine in the range of 0.05 to 5.0 weight % both inclusive;

(16) chemical solution containing anti-corrosive;

The above-mentioned chemical solution may be used singly or in combination.

If the first chemical solution step is characterized by a step of applying chemical solution for removal to an alterated or deposited layer formed on a surface of an organic film pattern, and the second chemical solution step is characterized by (A) a step of developing an organic film pattern through the use of chemical solution having a function of developing the organic film pattern, (B) a step of developing an organic film pattern through the use of chemical solution having a function of developing at least the organic film pattern, (C) a N-th step of developing an organic film pattern, wherein N indicates an integer equal to or greater than two, or (D) a chemical solution step of applying chemical solution not having a function of developing an organic film pattern, but having a fusing an organic film pattern for removal, to the organic film pattern, the first or second chemical solution step is selected in the present invention in accordance with performance and/or function of them.

However, both of the first and second chemical solution steps may be selected, because a combination of the first and second chemical solution steps is necessary to have the desired result.

Specifically, the above-mentioned chemical solutions (5) to (15) are principally used in the first chemical solution step, and the above-mentioned chemical solutions (1) to (4) are principally used in the second chemical solution step.

However, the above-mentioned chemical solutions (5) to (15) may be used in the second chemical solution step, and the above-mentioned chemical solutions (1) to (4) may be used in the first chemical solution step.

In the third heating step S8, a stage of the heating unit 18 is kept at a predetermined temperature (for instance, a temperature in the range of 80 to 180 degrees centigrade), and a substrate is placed on the stage for a predetermined period of time (for instance, 3 to 5 minutes). The third heating step recovers an organic film pattern from damages caused to the organic film pattern by the third removal step (chemical solution step or ashing step), or puts an organic film pattern into a stable condition similarly to the organic film pattern being post-baked after being developed.

In the first embodiment, there is used the apparatus 100 or 200 including at least the chemical solution process unit 21, the temperature controlling unit 19, the gas atmosphere unit 22, and the heating unit 18 as the process units U1 to U7 or U1 to U9.

In the apparatus 100, the chemical solution process unit 21, the temperature controlling unit 19, the gas atmosphere unit 22, and the heating unit 18 may be arranged arbitrarily.

The apparatus 100 may be designed to further include the simple light-exposure unit 17, the ashing unit 23, the chemical solution unit 21, the temperature controlling unit 19, and the heating unit 18. The apparatus 100 may include a plurality of certain units in accordance with a capacity of each unit.

In contrast, in the apparatus 200, the temperature controlling unit 19, the gas atmosphere unit 22, the heating unit 18, the temperature controlling unit 19, the chemical solution unit 21, and the heating unit 18 are necessary to be arranged in this order in a direction indicated with an arrow A in FIG. 6.

The apparatus 200 may be designed to further include the simple light-exposure unit 17, the ashing unit 23, the chemical solution unit 21, the temperature controlling unit 19, and the heating unit 18. The apparatus 100 may include a plurality of certain units in accordance with a capacity of each unit.

In the methods explained hereinafter, it is also necessary to arrange those process units in the order in the apparatus 200.

In accordance with the first embodiment, by carrying out the third removal step J3, a part of an organic film pattern (for instance, a resist pattern) having an area having been increased more than necessity in the fusion/deformation reflow, among the organic film pattern having been fused and deformed in the gas atmosphere step S3, is removed. Thus, it is possible to pattern an organic film pattern into a desired pattern with high accuracy.

The fusion/deformation step or the gas atmosphere step S3 causes an organic film pattern to deform in the range of 5 to 20 micrometers (it is possible to deform an organic film pattern by 100 micrometers or more).

However, since an organic film pattern is much deformed, if the organic film pattern is required to be accurately patterned, it would be necessary to accurately control the deformation of the organic film pattern.

In order to reduce a number of photolithography steps, there may be used an organic film pattern (specifically, a resist pattern) for forming a source and a drain in a channel. The fusion/deformation step is used for deforming two separate portions of the resist pattern located in the vicinity of a channel, corresponding to the source and drain, thereby unifying the separate two portions to each other.

It is necessary to cause much “chemical solution fusion reflow” in order to stably unify the separate two portions to each other. However, if “chemical solution fusion reflow” is carried out so much, a resist pattern associated with portions other than a channel, such as wirings, would be much fused and deformed.

Since an area of an organic film pattern is increased in the fusion/deformation step, it was necessary to accurately control a period of time for carrying out the gas atmosphere step to avoid an organic film pattern from having an area increased more than necessity.

The third removal step J3 contracts or reduces an area of an organic film pattern.

In the third removal step, after an organic film pattern formed on a substrate has been fused and thereby deformed, at least a part of an unnecessary portion of the organic film pattern and a portion of the organic film pattern having an area having increased more than necessity are removed by various processes.

Whereas the conventional method has only a control to an increasing area of the organic film pattern, for instance, by controlling a period of time for carrying out the fusion/deformation reflow process, the method in accordance with the first embodiment has not only the above-mentioned control, but also a second control for removing a part of the fused/deformed organic film pattern or reducing an area of the fused/deformed organic film pattern. Thus, the method in accordance with the first embodiment makes it possible to accurately control the deformation of the organic film pattern.

When the method in accordance with the first embodiment is used for reducing a number of photolithography steps, it would be possible, by carrying out the third removal step, to pattern the organic film pattern so as to have a desired area by removing a part of the fused/deformed organic film pattern or reducing an area of the fused/deformed organic film pattern after the organic film pattern was reflowed by the fusion/deformation step.

The third removal step may be comprised of the second chemical solution step as a wet process and an ashing step as a dry process singly or in combination.

Ashing as a dry step can be grouped into two types.

A first type of ashing is a step other than plasma-discharging steps. For instance, a first type of ashing is comprised of a step of applying optical energy of a light having a short wavelength such as ultra-violet ray, or heat to an object such as an organic film or an underlying film. The first type of ashing exerts less damage on an object, but has a low processing speed. Accordingly, the first type of ashing is used merely for changing a surface condition of an organic film pattern or an underlying film, and is hardly used for a process required to be carried out at a high rate, such as removal of an alterated layer formed on an organic film.

A second type of ashing is a plasma-discharging step. A plasma-discharging step is grouped further into types one and two. A type one is an isotropic plasma-discharging step to be carried out under a high pressure with low power, and a type two is an anisotropic plasma-discharging step to be carried out under a low pressure with high power. Both of the type one and two have a process speed higher than that of the first type of ashing, that is, a step other than plasma-discharging steps, and the type two has a higher process speed than the same of the type one. Thus, since the type one and two have a high process speed, an organic film pattern can be etched in a short period of time, and a surface of an underlying film can be changed in a short period of time. In addition, the type one and two can be carried out for removal of an alterated layer formed on a surface of an organic film pattern, or a high-speed process such as dry peeling-off. However, the second type of ashing, that is, a plasma-discharging step exerts more damage to an object than the first type of ashing.

In particular, an alterated layer formed on an organic film pattern cannot be sufficiently removed by the first type of ashing. An anisotropic plasma-discharging step (type two) can sufficiently remove an initially formed alterated layer, but would exert much damage to an organic film pattern, and resultingly, an alterated layer is newly formed on the organic film pattern. Accordingly, it is meaningless to select an anisotropic plasma-discharging step (type two) for removing an alterated layer formed on a surface of an organic film pattern. Thus, an isotropic plasma-discharging step (type one) is usually selected for removing an alterated layer formed on a surface of an organic film pattern.

However, in the method suggested in the above-mentioned Japanese Patent Application Publication No. 2002-334830, when an alterated layer formed on a surface of an organic film pattern is removed for uniformizing a step of causing chemical (for instance, organic solvent) to percolate into an organic film pattern for deforming the organic film pattern, it would be impossible to completely remove the alterated layer even by the anisotropic plasma-discharging step (type two) and the isotropic plasma-discharging step (type one), and it would be also impossible to prevent a small alterated layer from being formed on an organic film pattern due to damage newly exerted by the anisotropic and isotropic plasma-discharging step.

The inventor found out the problem that even such a small alterated layer newly formed due to the plasma-discharging step prevents uniformity of a step of causing chemical to percolate into an organic film pattern for deforming the organic film pattern.

That is, the method suggested in the above-mentioned Publication is accompanied with a problem that since a step of causing chemical percolating into an organic film pattern is insufficiently carried out as a result that the organic film pattern is damaged by a plasma-discharging step and that a small alterated film is newly formed on the organic film pattern, a step of etching an underlying film is insufficiently carried out.

In accordance with the present invention, removal of an alterated or deposited layer formed at a surface of an organic film pattern, which was carried out by ashing in a conventional method, is carried out by a wet step, specifically, a step of applying chemical to an organic film pattern. Hence, it is possible to prevent an organic film pattern or a substrate from being damaged.

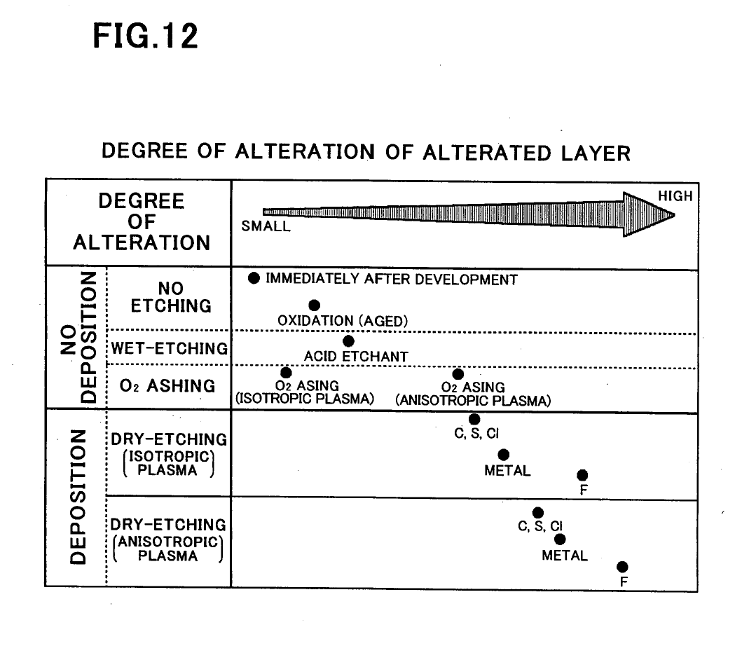

One of the above-mentioned variants 1 to 4 is selected as the third removal step J3 taking into consideration the above-mentioned matter and the matter mentioned later with reference to FIGS. 12 to 15.

The step S4 of heating an organic film pattern may be omitted, in which case, it is unnecessary for the apparatus 100 or 200 to have the second process unit 18.

If a temperature at which an organic film pattern is heated in the second process unit 18 can be accomplished also in the third process unit 19, the step S4 may be carried out in the third process unit 19. In FIGS. 2, 9 and 10, a step sandwiched between parentheses may be omitted, similarly to the step S4. In addition, a process unit associated with a step sandwiched between parentheses may be also omitted.

It is preferable that a substrate is cooled down to a room temperature after the step S4 has been carried out.

Even if a common step is carried out N times (N is an integer equal to or greater than two), the apparatus 100 is not necessary to include common process units for carrying out the step, but the apparatus 200 is necessary to include N common process units for carrying out the step. For instance, if the step S4 has to be carried out twice in the apparatus 200, the apparatus 200 has to include two sixth process units 22. The same is applied to the methods explained hereinbelow.

### Second Embodiment

The method in accordance with the second embodiment of the present invention is explained hereinbelow.

The method in accordance with the second embodiment of the present invention is carried out for the above-mentioned purposes (A) to (C), similarly to the first embodiment. In other words, the method in accordance with the second embodiment relates to steps of processing an organic film pattern for the purposes (A) to (C).

FIG. 1B is a flow-chart showing steps to be carried out in the method in accordance with the second embodiment of the present invention.

As illustrated in FIG. 1B, the method in accordance with the second embodiment includes, in sequence of, a first removal step J1, a temperature controlling step S2, a gas atmosphere step S3, a second heating step S4, a temperature controlling step S2, a third removal step J3, and a third heating step S8.

The temperature controlling step S2, the second heating step S4, and the third heating step S8 embraced with broken-line brackets in FIG. 1B may be omitted.

Furthermore, the second heating step S4, the third heating step S8, and the temperature controlling step S2 may be carried out by changing a temperature range in a processing unit prepared for carrying out those steps.

The method in accordance with the second embodiment can have variants as follows.

### (Variant 1)

The method in accordance with the variant 1 includes, in sequence of, a first removal step J1 of removing at least an alterated layer or a deposited layer formed at a surface of an organic film pattern, a gas-atmosphere step S3 of exposing the organic film pattern to gas atmosphere to thereby fuse and deform an organic film pattern, and a third removal step J3 of removing at least a part of the fused/deformed organic film pattern.

### (Variant 2)

The method in accordance with the variant 2 includes, in sequence of, a first removal step J1 of removing at least an alterated layer or a deposited layer formed at a surface of an organic film pattern, a gas-atmosphere step S3 of exposing the organic film pattern to gas atmosphere to thereby fuse and deform an organic film pattern, a second heating step S4 of heating the fused/deformed organic film pattern, and a third removal step J3 of removing at least a part of the fused/deformed organic film pattern.

### (Variant 3)

The method in accordance with the variant 3 includes, in sequence of, a first removal step J1 of removing at least an alterated layer or a deposited layer formed at a surface of an organic film pattern, a gas-atmosphere step S3 of exposing the organic film pattern to gas atmosphere to thereby fuse and deform an organic film pattern, a second heating step S4 of heating the fused/deformed organic film pattern, a third removal step J3 of removing at least a part of the fused/deformed organic film pattern, a third heating step S8 of heating the fused/deformed organic film pattern.

### (Variant 4)

The method in accordance with the variant 4 includes, in sequence of, a first removal step J1 of removing at least an alterated layer or a deposited layer formed at a surface of an organic film pattern, a first heating step S9 of heating an organic film pattern, a gas-atmosphere step S3 of exposing the organic film pattern to gas atmosphere to thereby fuse and deform an organic film pattern, a second heating step S4 of heating the fused/deformed organic film pattern, a third removal step J3 of removing at least a part of the fused/deformed organic film pattern, a third heating step S8 of heating the fused/deformed organic film pattern.

The variants 1 to 4 may include a temperature controlling step of keeping a temperature of a substrate constant. The temperature controlling step is carried out immediately before the fusion/deformation step S3.

As explained above, the method in accordance with the second embodiment necessarily includes the first removal step J1, the gas-atmosphere step S3 and the third removal step J3, and other steps may be omitted, if necessary.

The first removal step J1 may be comprised of the first chemical solution step of removing an alterated layer or a deposited layer formed at a surface of the organic film pattern through the use of acid solution, alkaline solution, organic solvent and so on, and an ashing step singly or in combination. The first removal step J1 is carried out in both of the chemical solution process unit 21 and the ashing unit 23.

By carrying out the first removal step J1, it is possible to remove an alterated layer or a deposited layer formed at a surface of the organic film pattern, and further, to enhance wettability of a surface of a substrate not covered with the organic film pattern.

In the first removal step J1, an alterated layer formed at a surface of an organic film pattern or a deposited layer formed at a surface of an organic film pattern is removed at least.

FIGS. 2A, 2B and 2C are flowcharts each showing a step or steps to be carried out in examples of the first removal step J1.

The first removal step J1 has three examples as follows.

As illustrated in FIG. 2A, a first example of the first removal step J1 is comprised of a first chemical solution step S1 for applying chemical solution to an organic film pattern to remove an alterated layer or a deposited layer formed at a surface of an organic film pattern.

As illustrated in FIG. 2B, a second example of the first removal step J1 is comprised of an ashing step S7 for ashing an organic film pattern.

As illustrated in FIG. 2C, a third example of the first removal step J1 is comprised of, in sequence of, an ashing step S7, and a first chemical solution step S1.

In the ashing step, films formed on a substrate are etched through the use of at least one of plasma, ozone and ultraviolet rays.

It is preferable in the first chemical solution step to determine a period of time for carrying out the first chemical solution step or to select chemical solution in order to selectively remove only an alterated layer or a deposited layer formed at a surface of an organic film pattern.

As a result of removal of the alterated or deposited layer, it is possible to cause a non-alterated portion of an organic film pattern to appear, or to cause a portion of an organic film pattern covered with a deposited layer to appear.

An alterated layer to be removed by the first removal step is formed as a result that a surface of an organic film pattern is alterated due to degradation caused by aging, thermal oxidation, heat curing, adhesion of a deposited layer thereto, acid etchant (etchant for wet etching), ashing (for instance, O₂ ashing), or dry etching gas.

That is, an organic film pattern is physically and chemically damaged and alterated due to the above-mentioned factors. A degree and character of alteration of an alterated layer depends highly on chemical solution to be used in wet-etching, whether plasma process as one of dry-etching is isotropic or anisotropic, whether deposition exists on an organic film pattern, and gas used in dry-etching. Hence, difficulty in removing an alterated layer depends also on those factors.

A deposited layer to be removed by the first removal step is formed as a result of dry etching.

A character of a deposited layer depends on whether plasma process as one of dry-etching is isotropic or anisotropic, and gas used in dry-etching. Hence, difficulty in removing a deposited layer depends also on those factors.

Accordingly, it is necessary to determine a period of time for carrying out the first chemical solution step, and chemical solution to be used in the first chemical solution step in accordance with difficulty in removing an alterated layer or a deposited layer.

As chemical solution to be used in the first chemical solution step, for instance, there is used one of chemical solution containing alkaline chemical, chemical solution containing acid chemical, chemical solution containing organic solvent, chemical solution containing both organic solvent and amine, and chemical solution containing alkaline and amine.

Alkaline chemical contains, for instance, amine and water, and organic solvent contains, for instance, amine.

Chemical solution containing anticorrosive may be used in the first chemical solution step.

Amine is selected from monoethyl amine, diethyl amine, triethyl amine, monoisopyl amine, diisopyl amine, triisoply amine, monobutyl amine, dibutyl amine, tributyl amine, hydroxylamine, diethylhydroxylamine, diethylhydroxyl amine anhydride, pyridine, or picoline.

Among the above-listed amine, one or more of amine may be contained in chemical solution.

For instance, chemical solution to used in the first chemical solution step is comprised of aqueous solution containing amine in the range of 0.01 to 10 weight % both inclusive.

The temperature control step S2 is carried out before the gas atmosphere step S3 in order to keep a temperature of an organic film pattern constant.

For instance, an organic film pattern is kept at a temperature in the range of 10 to 50 degrees centigrade by the temperature control step S2.

In the temperature control step S2, a substrate is kept placed on a stage of the temperature controlling unit 19 which is kept at a temperature at which gas atmosphere is carried out, until a temperature of the substrate reaches the above-mentioned temperature. For instance, a substrate is kept placed on the stage for 3 to 5 minutes.

The first chemical solution step and the temperature control step facilitate gas to penetrate an organic film pattern in a gas atmosphere step S3 to be later carried out, ensuring enhancement of a yield and quality of the gas atmosphere step.

The gas atmosphere step S3, the second heating step S4, the temperature control step S2, the third removal step J3 and the third heating step S8 are carried out similarly to the first embodiment.

An apparatus for processing a substrate, to be used in the second embodiment, is designed to include suitable one or ones among the units 17 to 23 illustrated in FIG. 7 in accordance with an order in which steps in the second embodiment are carried out and times at which steps in the second embodiment are carried out.

In comparison with an apparatus processing a substrate, to be used in the first embodiment, the apparatus for processing a substrate, to be used in the second embodiment, is necessary to additionally include a unit for carrying out the first removal step J1. For instance, the apparatus to be used in the second embodiment includes the chemical solution process unit 21 and/or the ashing unit 23. Except a unit for carrying out the first removal step J1, the apparatus to be used in the second embodiment includes the same units as the units included in the apparatus to be used in the first embodiment.

### Third Embodiment

The method in accordance with the third embodiment of the present invention is explained hereinbelow.

The method in accordance with the third embodiment of the present invention is carried out for the above-mentioned purposes (A) to (C), similarly to the first embodiment. In other words, the method in accordance with the third embodiment relates to steps of processing an organic film pattern for the purposes (A) to (C).

FIG. 1C is a flow-chart showing steps to be carried out in the method in accordance with the third embodiment of the present invention.

As illustrated in FIG. 1C, the method in accordance with the third embodiment includes, in sequence of, a first removal step J1, a second removal step J2, a temperature controlling step S2, a gas atmosphere step S3, a second heating step S4, a temperature controlling step S2, a third removal step J3, and a third heating step S8.

The temperature controlling step S2, the second heating step S4, and the third heating step S8 embraced with broken-line brackets in FIG. 1C may be omitted.

Furthermore, the second heating step S4, the third heating step S8, and the temperature controlling step S2 may be carried out by changing a temperature range in a processing unit prepared for carrying out those steps.

The method in accordance with the third embodiment can have variants as follows.

### (Variant 1)

The method in accordance with the variant 1 includes, in sequence of, a first removal step J1 of removing at least an alterated layer or a deposited layer formed at a surface of an organic film pattern, a second removal step J2 of removing a part of the organic film pattern, a gas-atmosphere step S3 of exposing the organic film pattern to gas atmosphere to thereby fuse and deform an organic film pattern, and a third removal step J3 of removing at least a part of the fused/deformed organic film pattern.

### (Variant 2)

The method in accordance with the variant 2 includes, in sequence of, a first removal step J1 of removing at least an alterated layer or a deposited layer formed at a surface of an organic film pattern, a second removal step J2 of removing a part of the organic film pattern, a gas-atmosphere step S3 of exposing the organic film pattern to gas atmosphere to thereby fuse and deform an organic film pattern, a second heating step S4 of heating the fused/deformed organic film pattern, and a third removal step J3 of removing at least a part of the fused/deformed organic film pattern.

### (Variant 3)

The method in accordance with the variant 3 includes, in sequence of, a first removal step J1 of removing at least an alterated layer or a deposited layer formed at a surface of an organic film pattern, a second removal step J2 of removing a part of the organic film pattern, a gas-atmosphere step S3 of exposing the organic film pattern to gas atmosphere to thereby fuse and deform an organic film pattern, a second heating step S4 of heating the fused/deformed organic film pattern, a third removal step J3 of removing at least a part of the fused/deformed organic film pattern, a third heating step S8 of heating the fused/deformed organic film pattern.

### (Variant 4)

The method in accordance with the variant 4 includes, in sequence of, a first removal step J1 of removing at least an alterated layer or a deposited layer formed at a surface of an organic film pattern, a second removal step J2 of removing a part of the organic film pattern, a first heating step S9 of heating an organic film pattern, a gas-atmosphere step S3 of exposing the organic film pattern to gas atmosphere to thereby fuse and deform an organic film pattern, a second heating step S4 of heating the fused/deformed organic film pattern, a third removal step J3 of removing at least a part of the fused/deformed organic film pattern, a third heating step S8 of heating the fused/deformed organic film pattern.

The variants 1 to 4 may include a temperature controlling step of keeping a temperature of a substrate constant. The temperature controlling step is carried out immediately before the fusion/deformation step S3.

As explained above, the method in accordance with the third embodiment necessarily includes the first removal step J1, the second removal step J2, the gas-atmosphere step S3 and the third removal step J3. Other steps may be omitted, if necessary.

The first removal step J1 to be carried out in the third embodiment is identical to the first removal step J1 to be carried out in the above-mentioned second embodiment.

The second removal step J2 is carried out after the first removal step J1 in which an alterated or deposited layer formed at a surface of an organic film pattern is removed has been carried out. In the second removal step J2, a part of the residual organic film pattern is removed. Herein, the residual organic film pattern is a non-alterated portion of the organic film pattern.

FIGS. 3A, 3B and 3C are flowcharts each showing a step or steps to be carried out in examples of the second removal step J2.

As illustrated in FIG. 3A, a first example of the second removal step J2 is comprised only of a second chemical solution step S5 for applying chemical solution to an organic film pattern. The chemical solution used in the first example has a function of developing an organic film pattern or a function of separating an organic film pattern.

As illustrated in FIG. 3B, a second example of the second removal step J2 is comprised only of an ashing step S7 for ashing an organic film pattern.

As illustrated in FIG. 3C, a third example of the second removal step J2 is comprised of, in sequence of, an ashing step S7, and a second chemical solution step S5.

In the above-mentioned ashing step, films formed on a substrate are etched through the use of at least one of plasma, ozone and ultraviolet rays.

In the second removal step J2, an alterated or deposited layer formed at a surface of an organic film pattern may be removed.

The second chemical solution step in the third embodiment is carried out similarly to the second chemical solution step in the first embodiment.

The temperature control step S2 is carried out before the gas atmosphere step S3 in order to keep an organic film pattern at a constant temperature.

For instance, an organic film pattern is kept at a temperature in the range of 10 to 50 degrees centigrade by the temperature control step S2.

In the second heating step S4, a stage of the temperature control unit 19 is kept at a predetermined temperature at which the gas atmosphere step is carried out, and a substrate is placed on the stage for a predetermined period of time (for instance, 3 to 5 minutes).

The gas atmosphere step S3, the second heating step S4, the temperature control step S2, the third removal step J3 and the third heating step S8 are carried out similarly to the first embodiment.

An apparatus for processing a substrate, to be used in the third embodiment, is designed to include suitable unit or units among the units 17 to 23 illustrated in FIG. 7 in accordance with an order in which steps in the third embodiment are carried out and times at which steps in the third embodiment are carried out. The apparatus may include a plurality of the same units in dependence on a particular step or steps.

In comparison with an apparatus processing a substrate, to be used in the first embodiment, the apparatus for processing a substrate, to be used in the third embodiment, is necessary to additionally include both a unit for carrying out the first removal step J1 and a unit for carrying out the second removal step J2. For instance, the apparatus to be used in the third embodiment includes the chemical solution process unit 21 and/or the ashing unit 23. Except a unit for carrying out the first removal step J1 and a unit for carrying out the second removal step J2, the apparatus to be used in the third embodiment includes the same units as the units included in the apparatus to be used in the first embodiment.

Hereinbelow is explained a step of exposing an organic film pattern to light, to be carried out in the first, second and third embodiments.

The step of exposing an organic film pattern to light is grouped into a step of exposing an organic film pattern to light through the use of a mask having a minute pattern, and a step of exposing an organic film pattern to light in an area covering therewith a predetermined area (which may be an entire area of a substrate) of a substrate. The latter step is hereinafter referred to as “simple light-exposure step”.

The simple light-exposure step is carried out in the simple light-exposure unit 17. In the simple light-exposure unit 17, an organic film pattern is exposed to ultra-violet ray, fluorescent light, natural light, and other similar lights.

In the simple light-exposure step, an organic film pattern covering a part or all of a substrate therewith is exposed to light. For instance, an organic film pattern covering 1/10 or more of a total area of a substrate therewith is exposed to light.

In the simple light-exposure step, an organic film pattern may be exposed to light at a time in an area corresponding to a predetermined area of a substrate, or an organic film pattern may be scanned with spot light in an area corresponding to a predetermined area of a substrate.

In the first, second and third embodiments, it is preferable that a substrate is kept not exposed to light after initial exposure of a substrate to light for forming an organic film pattern, until development of the organic film pattern is carried out.

By doing so, it would be possible to uniformize effect of development of an organic film pattern, and further uniformize exposure of a substrate to light in the simple light-exposure step. In order to keep a substrate not exposed to light, all steps may be administrated for this end, or the apparatus 100 or 200 may be designed to have a function of doing so.

The simple light-exposure step may be carried out in such a manner as mentioned below.

In a first case, an organic film pattern formed on a substrate kept not exposed to light before the simple light-exposure step is carried out is exposed to light in the simple light-exposure step.

In a second case, when a substrate is exposed to light to some degree before the simple light-exposure step is carried out, or how degree a substrate is exposed to light is unknown, the simple light-exposure step is carried out for entirely exposing a substrate to light for uniformizing exposure of a substrate to light, or for additionally exposing a substrate to light for precaution.

The ashing step may be comprised of a dry step such as a step of applying plasma to an organic film pattern in oxygen atmosphere or in oxygen/fluorine atmosphere, a step of applying optical energy of light having a short wavelength such as ultra-violet ray, to an organic film pattern, or a step of applying ozone to an organic film pattern through the use of such optical energy and heat.

The above-mentioned alterated layer formed on an organic film pattern, to be removed in the ashing step, is caused due to degradation caused by aging, thermal oxidation, heat curing, adhesion of a deposition layer thereto, acid etchant (wet-etching), O₂ ashing, and other dry etching gases (dry-etching).

An organic film pattern is physically or chemically damaged and thus deformed due to the above-mentioned factors. A degree and character of alteration of an alterated layer depends highly on chemical solution to be used in wet-etching, whether plasma process as one of dry-etching is isotropic or anisotropic, whether deposition exists on an organic film pattern, and gas used in dry-etching. Hence, difficulty in removing an alterated layer depends also on those factors.

A deposited layer formed at a surface of an organic film pattern, to be removed by the ashing step, is caused by dry etching.

A character of a deposited layer depends on whether plasma process as one of dry-etching is isotropic or anisotropic, and gas used in dry-etching. Hence, difficulty in removing a deposited layer depends also on those factors.

Ashing as a dry step can be grouped into two types.

A first type of ashing is a step other than plasma-discharging steps. For instance, a first type of ashing is comprised of a step of applying optical energy of a light having a short wavelength such as ultra-violet ray, or heat to an object such as an organic film or an underlying film. The first type of ashing exerts less damage on an object, but has a low processing speed. Accordingly, the first type of ashing is used merely for changing a surface condition of an organic film pattern or an underlying film, and is hardly used for a process required to be carried out at a high rate, such as removal of an alterated layer formed on an organic film.

A second type of ashing is a plasma-discharging step. A plasma-discharging step is grouped further into types one and two. A type one is an isotropic plasma-discharging step to be carried out under a high pressure with low power, and a type two is an anisotropic plasma-discharging step to be carried out under a low pressure with high power. Both of the type one and two have a process speed higher than that of the first type of ashing, that is, a step other than plasma-discharging steps, and the type two has a higher process speed than the same of the type one. Thus, since the type one and two have a high process speed, an organic film pattern can be etched in a short period of time, and a surface of an underlying film can be changed in a short period of time. In addition, the type one and two can be carried out for removal of an alterated layer formed on a surface of an organic film pattern, or a high-speed process such as dry peeling-off. However, the second type of ashing, that is, a plasma-discharging step exerts more damage to an object than the first type of ashing.

In particular, an alterated layer formed on an organic film pattern cannot be sufficiently removed by the first type of ashing. An anisotropic plasma-discharging step (type two) can sufficiently remove an initially formed alterated layer, but would exert much damage to an organic film pattern, and resultingly, an alterated layer is newly formed on the organic film pattern. Accordingly, it is meaningless to select an anisotropic plasma-discharging step (type two) for removing an alterated layer formed on a surface of an organic film pattern. Thus, an isotropic plasma-discharging step (type one) is usually selected for removing an alterated layer formed on a surface of an organic film pattern.

However, in the method suggested in the above-mentioned Japanese Patent Application Publication No. 2002-334830, when an alterated layer formed on a surface of an organic film pattern is removed for uniformizing a step of causing chemical (for instance, organic solvent) to percolate into an organic film pattern for deforming the organic film pattern, it would be impossible to completely remove the alterated layer even by the anisotropic plasma-discharging step (type two) and the isotropic plasma-discharging step (type one), and it would be also impossible to prevent a small alterated layer from being formed on an organic film pattern due to damage newly exerted by the anisotropic and isotropic plasma-discharging step.

The inventor found out the problem that even such a small alterated layer newly formed due to the plasma-discharging step prevents uniformity of a step of causing chemical to percolate into an organic film pattern for deforming the organic film pattern.

That is, the method suggested in the above-mentioned Publication is accompanied with a problem that since a step of causing chemical percolating into an organic film pattern is insufficiently carried out as a result that the organic film pattern is damaged by a plasma-discharging step and that a small alterated film is newly formed on the organic film pattern, a step of etching an underlying film is insufficiently carried out.

The above-mentioned Publications Nos. 2005-159292 and 2005-159342 provide a solution to the above-mentioned problem. That is, they suggest a method of processing a substrate and chemical solution used in the method, both of which are capable of preventing an organic film pattern and a substrate from being damaged.

The present invention covers both of the above-mentioned steps.

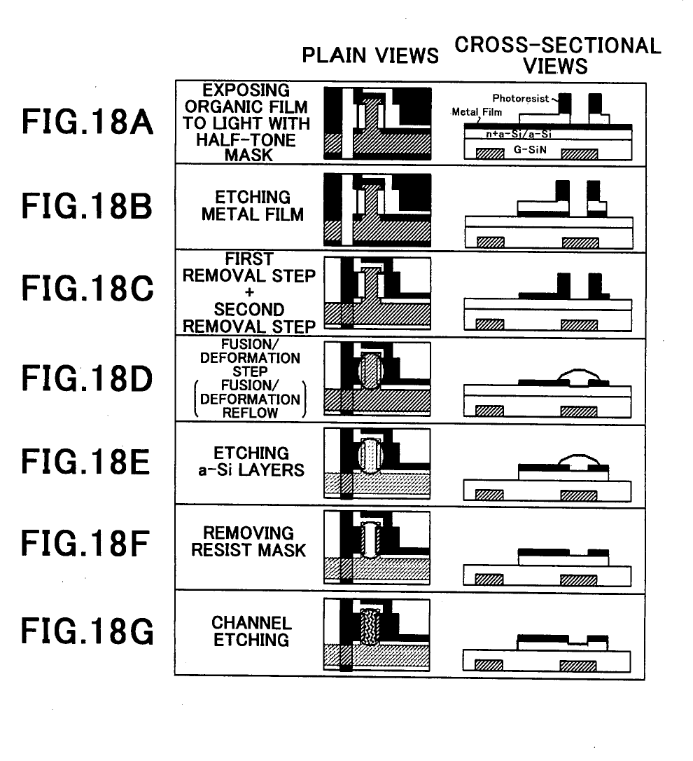

FIGS. 18A to 18G are plan and cross-sectional views of a thin film transistor (TFT) device in a conventional method of fabricating a TFT substrate, including a conventional fusion/deformation/reflow process.

First, as illustrated in FIG. 18A, a gate wire is formed on a glass substrate.

Then, an interlayer insulating film, an amorphous silicon (a-Si) layer, an ohmic contact (n+ a-Si) layer, and a metal film for a drain are formed so as to cover the gate wire therewith. For instance, the interlayer insulating film is comprised of a silicon oxide film (SiO₂) and/or a silicon nitride film (SiNx).

The ohmic contact layer is comprised of a n-type amorphous silicon (n+a-Si) layer into which impurity of phosphorus is doped.

Then, an organic film (for instance, a resist film) is formed.

Then, the organic film is patterned by exposing the organic film to light through the use of a mask (specifically, a half-tone mask), and developing the organic film. Hereinbelow, the thus patterned organic film is referred to as a resist pattern. The resist pattern has two different thicknesses.

Then, as illustrated in FIG. 18B, the metal film is etched with the resist pattern being used as a mask.

By being etched, the metal film is turned into source/drain electrodes and source/drain wirings.

Then, as illustrated in FIG. 18C, at least a part of the resist pattern is removed by the second removal step or a combination of the first and second removal steps.

A thicker portion of the resist pattern is removed among the two portions of the resist pattern having different thicknesses.

The first and second removal steps are carried out similarly to the first and second removal steps carried out in the third embodiment except that the second removal step is comprised principally of a step developing an organic film pattern through the use of chemical solution having a function of developing the organic film pattern.

Then, as illustrated in FIG. 18D, a fusion/deformation step (fusion/deformation reflow) is carried out to the resist pattern.

The fusion/deformation step is comprised of the gas atmosphere step S3 having been referred to in the first embodiment.

By carrying out the fusion/deformation step, a resist mask for a source electrode and a resist mask for a drain electrode are latitudinally reflowed to join with each other. Namely, there is formed a joint resist mask.

Then, as illustrated in FIG. 18E, the amorphous silicon (a-Si) layer and the ohmic contact (n+ a-Si) layer are etched into a semiconductor island through the use of the joint resist mask and further through the use of electrodes for source and drain and wirings for source and drain as a mask.

Then, as illustrated in FIG. 18F, the joint resist mask is removed.

Then, as illustrated in FIG. 18G, a channel etching is carried out such that at least the ohmic contact (n+ a-Si) layer is removed between a source and a drain among the amorphous silicon (a-Si) layer and the ohmic contact (n+ a-Si) layer, with the electrodes for source and drain and the wirings for source and drain both being as a mask, and the at least a part of the amorphous silicon (a-Si) layer remains as it is.

Hereinafter, a passivation film comprised of an electrically insulating film (generally, a plasma-nitrided silicon film) is formed. Contact holes are formed above the source and drain electrodes. Then, there are formed a pixel electrode which electrically connects to a source electrode at a bottom of the contact hole, and a terminal electrode which electrically connects to a drain electrode at a bottom of the contact hole.

A TFT substrate is fabricated in accordance with the above-mentioned steps. Then, an opposing substrate is arranged in facing relation with the semiconductor island of the TFT substrate. A space formed between the TFT substrate and the opposing substrate is filled with liquid crystal. Thus, there is fabricated a liquid crystal display device.

### Fourth Embodiment

Hereinbelow is explained, as the fourth embodiment, a method of fabricating a TFT substrate used for a liquid crystal display device, including the fusion/deformation reflow step and the step of removing a part of the fused/deformed organic film pattern.

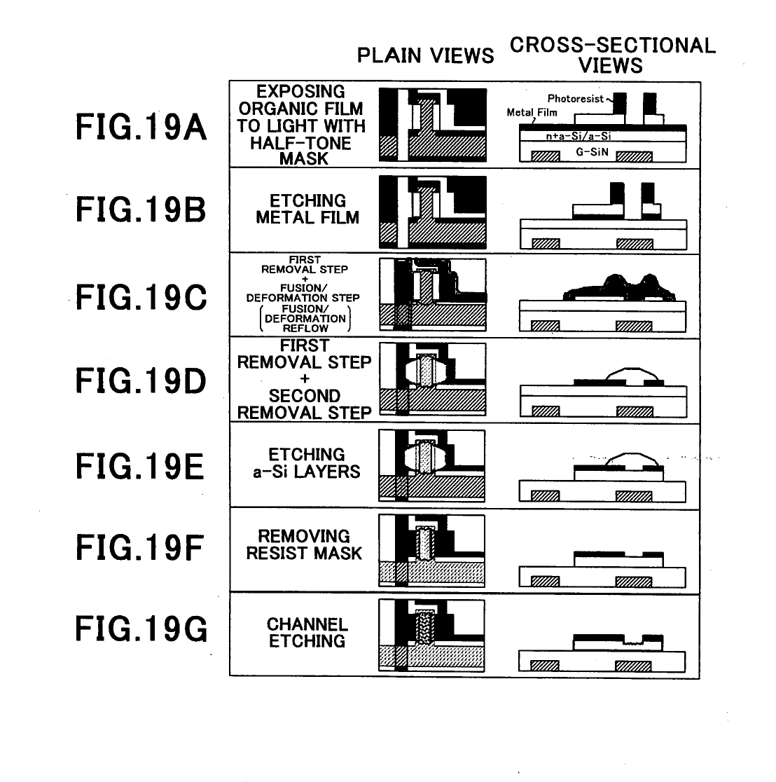

FIGS. 19A to 19G are plan and cross-sectional views of a thin film transistor (TFT) device in a method of fabricating a TFT substrate, in accordance with the fourth embodiment.

First, as illustrated in FIG. 19A, a gate wire is formed on a glass substrate.

Then, an interlayer insulating film, an amorphous silicon (a-Si) layer, an ohmic contact (n+ a-Si) layer, and a metal film for a drain are formed so as to cover the gate wire therewith. For instance, the interlayer insulating film is comprised of a silicon oxide film (SiO₂) and/or a silicon nitride film (SiNx).

The ohmic contact layer is comprised of a n-type amorphous silicon (n+a-Si) layer into which impurity of phosphorus is doped.

Then, an organic film (for instance, a resist film) is formed.

Then, the organic film is patterned by exposing the organic film to light through the use of a mask (specifically, a half-tone mask), and developing the organic film. Hereinbelow, the thus patterned organic film is referred to as a resist pattern. The resist pattern has two different thicknesses.

Then, as illustrated in FIG. 19B, the metal film is etched with the resist pattern being used as a mask.

By being etched, the metal film is turned into source/drain electrodes and source/drain wirings.

Then, as illustrated in FIG. 19C, the fusion/deformation (fusion/deformation reflow) step is carried out to the resist pattern.

The fusion/deformation step is comprised of the gas atmosphere step S3 having been referred to in the first embodiment.

By carrying out the fusion/deformation step, a resist mask for a source electrode and a resist mask for a drain electrode are latitudinally reflowed to join with each other. Namely, there is formed a joint resist mask.

If necessary, the first removal step may be carried out prior to the fusion/deformation step, in which case, the first removal step is carried out similarly to the first removal step carried out in the second embodiment.

The first removal step is carried out for the purpose of removing an alterated or deposited layer formed on or around the resist pattern. Chemical solution is selected to comply with the purpose.

Then, as illustrated in FIG. 19D, at least a part of the resist pattern is removed by the second removal step or a combination of the first and second removal steps.

A thicker portion of the resist pattern is removed among the two portions of the resist pattern having different thicknesses.

The first and second removal steps are carried out similarly to the first and second removal steps carried out in the third embodiment.

The second removal step is comprised principally of a step of developing the resist pattern through the use of a developing agent. By carrying out the second removal step, a portion of the resist pattern having an area having increased due to the fusion/deformation reflow, that is, an unnecessary portion of the resist pattern is removed, ensuring that the resist pattern is accurately patterned into a target pattern.

Then, as illustrated in FIG. 19E, the amorphous silicon (a-Si) layer and the ohmic contact (n+ a-Si) layer are etched into a semiconductor island through the use of the joint resist mask and further through the use of electrodes for source and drain and wirings for source and drain as a mask.

Then, as illustrated in FIG. 19F, the joint resist mask is removed.

Then, as illustrated in FIG. 19G, a channel etching is carried out such that at least the ohmic contact (n+ a-Si) layer is removed between a source and a drain among the amorphous silicon (a-Si) layer and the ohmic contact (n+ a-Si) layer, with the electrodes for source and drain and the wirings for source and drain both being as a mask, and the at least a part of the amorphous silicon (a-Si) layer remains as it is.

Hereinafter, a passivation film comprised of an electrically insulating film (generally, a plasma-nitrided silicon film) is formed. Contact holes are formed above the source and drain electrodes. Then, there are formed a pixel electrode which electrically connects to a source electrode at a bottom of the contact hole, and a terminal electrode which electrically connects to a drain electrode at a bottom of the contact hole.

A TFT substrate is fabricated in accordance with the above-mentioned steps. Then, an opposing substrate is arranged in facing relation with the semiconductor island of the TFT substrate. A space formed between the TFT substrate and the opposing substrate is filled with liquid crystal. Thus, there is fabricated a liquid crystal display device.

The channel etching may be carried out after the step of etching the metal film, illustrated in FIG. 19B, in which case, the step of carrying out the channel etching illustrated in FIG. 19G is omitted, or at least a part of the amorphous silicon (a-Si) layer in a channel area having been contaminated or alterated is etched or surface-treated. However, it is necessary to remain most of the amorphous silicon (a-Si) layer non-etched or as it is.

### Fifth Embodiment

Hereinbelow is explained, as the fifth embodiment, a second example of a method of fabricating a TFT substrate used for a liquid crystal display device, including the fusion/deformation reflow step and the step of removing a part of the fused/deformed organic film pattern.

Whereas a half-tone mask was used in the fourth embodiment, a half-tone mask is not used, but an ordinary mask is used in the fifth embodiment.

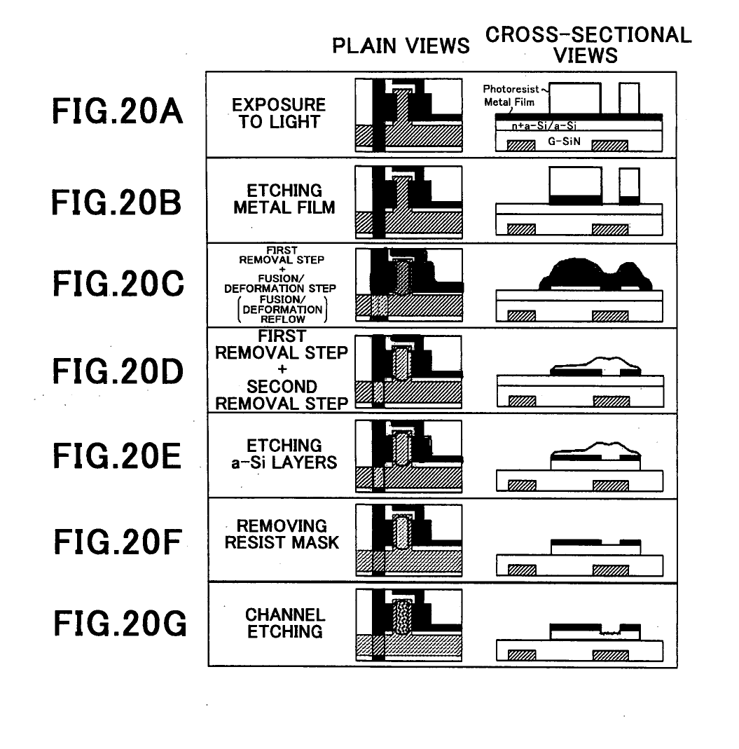

FIGS. 20A to 20G are plan and cross-sectional views of a thin film transistor (TFT) device in a method of fabricating a TFT substrate, in accordance with the fifth embodiment.

First, as illustrated in FIG. 20A, a gate wire is formed on a glass substrate.

Then, an interlayer insulating film, an amorphous silicon (a-Si) layer, an ohmic contact (n+ a-Si) layer, and a metal film for a drain are formed so as to cover the gate wire therewith. For instance, the interlayer insulating film is comprised of a silicon oxide film (SiO₂) and/or a silicon nitride film (SiNx).

The ohmic contact layer is comprised of a n-type amorphous silicon (n+a-Si) layer into which impurity of phosphorus is doped.

Then, an organic film (for instance, a resist film) is formed.

Then, the organic film is patterned by exposing the organic film to light through the use of a mask (specifically, not a half-tone mask, but a standard mask), and developing the organic film. Hereinbelow, the thus patterned organic film is referred to as a resist pattern. The resist pattern has two different thicknesses.

Then, as illustrated in FIG. 20B, the metal film is etched with the resist pattern being used as a mask.

By being etched, the metal film is turned into source/drain electrodes and source/drain wirings.

Then, as illustrated in FIG. 20C, the fusion/deformation (fusion/deformation reflow) step is carried out to the resist pattern.

The fusion/deformation step is comprised of the gas atmosphere step S3 having been referred to in the first embodiment.

By carrying out the fusion/deformation step, a resist mask for a source electrode and a resist mask for a drain electrode are latitudinally reflowed to join with each other. Namely, there is formed a joint resist mask.

If necessary, the first removal step may be carried out prior to the fusion/deformation step, in which case, the first removal step is carried out similarly to the first removal step carried out in the second embodiment.

The first removal step is carried out for the purpose of removing an alterated or deposited layer formed on or around the resist pattern. Chemical solution is selected to comply with the purpose.

Then, as illustrated in FIG. 20D, at least a part of the resist pattern is removed by the second removal step or a combination of the first and second removal steps.

A thicker portion of the resist pattern is removed among the two portions of the resist pattern having different thicknesses.

The first and second removal steps are carried out similarly to the first and second removal steps carried out in the third embodiment.

The second removal step is comprised principally of a step of developing the resist pattern through the use of a developing agent. By carrying out the second removal step, a portion of the resist pattern having an area having increased due to the fusion/deformation reflow, that is, an unnecessary portion of the resist pattern is removed, ensuring that the resist pattern is accurately patterned into a target pattern.

Then, as illustrated in FIG. 20E, the amorphous silicon (a-Si) layer and the ohmic contact (n+ a-Si) layer are etched into a semiconductor island through the use of the joint resist mask and further through the use of electrodes for source and drain and wirings for source and drain as a mask.

Then, as illustrated in FIG. 20F, the joint resist mask is removed.

Then, as illustrated in FIG. 20G, a channel etching is carried out such that at least the ohmic contact (n+ a-Si) layer is removed between a source and a drain among the amorphous silicon (a-Si) layer and the ohmic contact (n+ a-Si) layer, with the electrodes for source and drain and the wirings for source and drain both being as a mask, and the at least a part of the amorphous silicon (a-Si) layer remains as it is.

Hereinafter, a passivation film comprised of an electrically insulating film (generally, a plasma-nitrided silicon film) is formed. Contact holes are formed above the source and drain electrodes. Then, there are formed a pixel electrode which electrically connects to a source electrode at a bottom of the contact hole, and a terminal electrode which electrically connects to a drain electrode at a bottom of the contact hole.

A TFT substrate is fabricated in accordance with the above-mentioned steps. Then, an opposing substrate is arranged in facing relation with the semiconductor island of the TFT substrate. A space formed between the TFT substrate and the opposing substrate is filled with liquid crystal. Thus, there is fabricated a liquid crystal display device.

The channel etching may be carried out after the step of etching the metal film, illustrated in FIG. 20B, in which case, the step of carrying out the channel etching illustrated in FIG. 20G is omitted, or at least a part of the amorphous silicon (a-Si) layer in a channel area having been contaminated or alterated is etched or surface-treated. However, it is necessary to remain most of the amorphous silicon (a-Si) layer non-etched or as it is.

In the fourth and fifth embodiments, the gate electrode, the source electrode, the drain electrode and the metal film of the thin film transistor (TFT) may be comprised of any one of the following layers or structures:

(a) a single layer composed of aluminum or aluminum alloy;

(b) a single layer composed of chromium or chromium alloy;

(c) a two-layered structure including a layer composed of aluminum or aluminum alloy and a layer composed of chromium or chromium alloy;

(d) a two-layered structure including a layer composed of aluminum or aluminum alloy and a layer composed of titanium or titanium alloy;

(e) a two-layered structure including a layer composed of aluminum or aluminum alloy and a layer composed of titanium nitride or titanium nitride alloy;

(f) a two-layered structure including a layer composed of aluminum or aluminum alloy and a layer composed of molybdenum or molybdenum alloy;

(g) a two-layered structure including a layer composed of chromium or chromium alloy and a layer composed of molybdenum or molybdenum alloy;

(h) a three-layered structure including a layer composed of chromium or chromium alloy, a layer composed of molybdenum or molybdenum alloy, and a layer composed of chromium or chromium alloy;

(i) a three-layered structure including a layer composed of molybdenum or molybdenum alloy, a layer composed of aluminum or aluminum alloy, and a layer composed of molybdenum or molybdenum alloy;

(j) a three-layered structure including a layer composed of aluminum or aluminum alloy, a layer composed of molybdenum or molybdenum alloy, and a layer composed of chromium or chromium alloy;

(k) a three-layered structure including a layer composed of aluminum or aluminum alloy, a layer composed of molybdenum or molybdenum alloy, and a layer composed of titanium or titanium alloy; and

(l) a three-layered structure including a layer composed of aluminum or aluminum alloy, a layer composed of titanium nitride or titanium nitride alloy, and a layer composed of titanium or titanium alloy.

In the above-mentioned embodiments, a TFT substrate is designed to include a glass substrate, but may be designed to include an electrically insulating substrate other than a glass substrate.

The above-mentioned embodiments relate to a method of fabricating a pattern of a stagger type TFT. The method in accordance with the present invention may be applied, as well as a method of fabricating a pattern of a stagger type TFT, to a method of fabricating a TFT pattern including a step of forming either a color filter layer or a planarized layer and a color filter layer below a pixel electrode.

The above-mentioned embodiments are applied to a vertical electric field drive type liquid crystal display device. It should be noted that the above-mentioned embodiments may be applied to a horizontal electric field drive type liquid crystal display device such as an in-plane switching (IPS) type liquid crystal display device.

The methods in accordance with the fourth and fifth embodiments may be included in a method of fabricating a TFT. As an example of a TFT substrate, there is a TFT substrate used for a liquid crystal display device.

Before a pixel electrode composed of ITO, and an alignment film and other parts are formed on the TFT substrate, a color filter including an electrically insulating film, a color (RGB: red, green and blue) filter layer, a black matrix layer, and a transparent electrode, or a monochromatic filter is fabricated. Then, liquid crystal is sandwiched between the TFT substrate and the opposing substrate in a hermetically sealed condition. Then, a polarizing filter is attached to each of the substrates. Thus, there is completed a liquid crystal display device.

It is possible to control a thickness of a part of a resist mask as follows.

First, there is fabricated a reticle to be used in a step of exposing a resist film to light. The reticle has a mask pattern including a light-impermeable part, and light-permeable parts allowing light to pass therethrough in different degrees. The light-impermeable part and the light-permeable parts are transferred to a resist film to thereby form the above-mentioned resist mask.

As an alternative, two or more reticle masks are used in a step of exposing a resist film to light. An amount of light to which a resist film is exposed is changed in two steps, thereby the above-mentioned resist mask being fabricated.

In the above-mentioned method, a half-tone mask was used to form a resist pattern for controlling a thickness of portions of the resist mask. The half-tone mask is comprised of a reticle having a light-impermeable portion not allowing light to pass therethrough, and a portion allowing half of light to pass therethrough. Hereinbelow are explained examples of using a reticle.

In a first example, a light-impermeable portion not allowing light to pass therethrough, and a half-transmission portion allowing half of light to pass therethrough are formed on a reticle substrate.

The portions are composed of chromium. The half-transmission portion has a pattern composed of chromium and having a resolution equal to or smaller than maximum exposure resolution. For instance, the half-transmission portion has rectangular patterns arranged at a predetermined pitch, each pattern having a width equal to or smaller than exposure wavelength. As an alternative, the half-transmission portion such rectangular patterns arranged in a grid.

In the first example, light transmission of irradiated light for exposure is set in the range of 20 to 80% in the half-transmission portion, that is, in an area in which the above-mentioned chromium pattern having a resolution equal to or smaller than maximum exposure resolution is formed.

In a second example, a light-impermeable portion not allowing light to pass therethrough is formed on a reticle substrate in a predetermined pattern. The light-impermeable portion is composed of chromium. Chromium is etched into a thin film portion. In an area in which the thin film portion composed of chromium is formed, that is, in a half-transmission portion, light transmission of irradiated light for exposure is set about 50%.

In a third example, a light-impermeable portion not allowing light to pass therethrough is formed on a reticle substrate in a predetermined pattern. The light-impermeable portion is composed of chromium. A half-transmission portion in the third example is comprised of a half-tone portion. The half-tone portion is composed of tungsten silicide or molybdenum silicide, for instance.

Hereinbelow is explained a policy as to selection of the removal step to be carried out for removing an alterated or deposited layer formed at a surface of an organic film pattern in each of the above-mentioned first, second and third embodiments.

FIG. 12 illustrates a degree of alteration of an alterated layer in dependence on causes by which the alterated layer is formed. In FIG. 12, a degree of alteration is determined in accordance with difficulty in peeling off an alterated layer with a wet step.

As illustrated in FIG. 12, a degree of alteration of an alterated layer depends highly on a chemical to be used in wet-etching, whether dry-etching is isotropic or anisotropic, whether deposition exists on an organic film pattern, and gas used in dry-etching. Hence, difficulty in removing an alterated layer depends also on those.

As chemical used in the step of applying chemical to an organic film pattern, there is selected acid solution, alkaline solution or organic solvent alone or in combination.

Specifically, as the chemical is selected alkaline aqueous solution or aqueous solution containing at least one amine as organic solvent in the range of 0.01 to 10 weight % both inclusive.

Herein, amine is selected from monoethyl amine, diethyl amine, triethyl amine, monoisopyl amine, diisopyl amine, triisoply amine, monobutyl amine, dibutyl amine, tributyl amine, hydroxylamine, diethylhydroxylamine, diethylhydroxylamine anhydride, pyridine, or picoline.

If a degree of alteration of an alterated layer is relatively low, that is, if an alterated layer is formed due to oxidation caused by being aged, acid etchant or isotropic oxygen (O₂) ashing, the selected chemical may contain amine in the range of 0.05 to 5 weight % both inclusive.

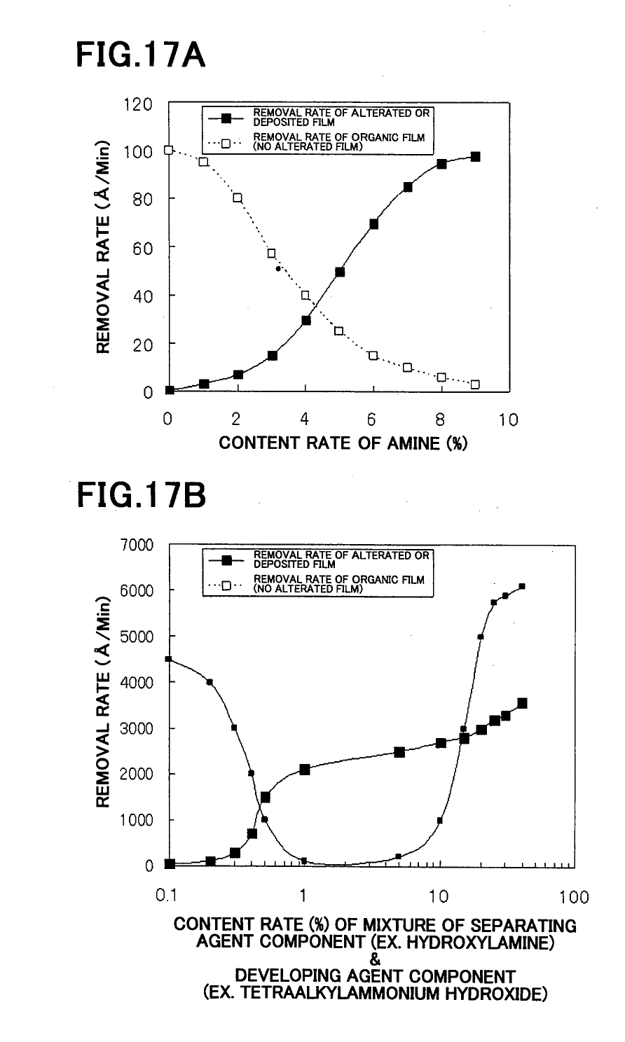

FIG. 17A is a graph showing relation between a concentration of amine in chemical solution and a removal rate, in association with whether an organic film pattern is alterated or not.

As illustrated in FIG. 17A, it is preferable that the chemical solution contains amine as organic solvent in the range of 0.05 to 2.0 weight % both inclusive in order to remove only an alterated layer and remain a non-alterated portion of an organic film pattern.

To this end, it is preferable to select hydroxylamine, diethylhydroxyl amine, diethylhydroxylamine anhydride, pyridine, or picoline to be contained in the chemical.

As an anticorrosive, there may be selected D-glucose (C₆H₁₂O₆), chelate or antioxidant.

By setting a suitable period of time for carrying out the step of applying chemical solution to an organic film pattern, as well as selecting suitable chemical solution, it would be possible to remove only an alterated or deposited layer, remain a non-alterated portion of an organic film pattern, or allow an organic film pattern having been covered with a deposited layer, to appear.

The step of applying chemical solution to an organic film pattern provides an advantage that organic solvent is likely to percolate into an organic film pattern in a fusion/deformation step to be carried out subsequently thereto.

Actually, by applying the above-mentioned chemical to an organic film pattern at a surface thereof, an alterated layer is cracked, or a part or all of an alterated layer is removed. Thus, it would be possible to avoid organic solvent from being prevented by an altered layer from penetrating an organic film pattern in a fusion/deformation step such as the step of applying gas atmosphere to an organic film pattern.

What is important is that a non-alterated portion of an organic film pattern should not be removed, but remains, and that organic solvent can readily penetrate a non-alterated portion of an organic film pattern by removing only an alterated layer or by cracking an alterated layer. It is necessary to select chemical solution allowing to do so.

As illustrated in FIGS. 2B, 2C, 3B, 3C, 4B and 4D, it is preferable that the ashing step is carried out prior to the step of applying chemical solution to an organic film pattern, when an alterated or deposited layer is firm or thick, or is quite difficult to remove, because the organic film pattern is combined with fluorine.

A combination of the ashing step and the step of applying chemical solution to an organic film pattern solves a problem that it is quite difficult to remove an alterated layer only by carrying out the step of applying chemical solution to an organic film pattern, or it takes much time to do the same.

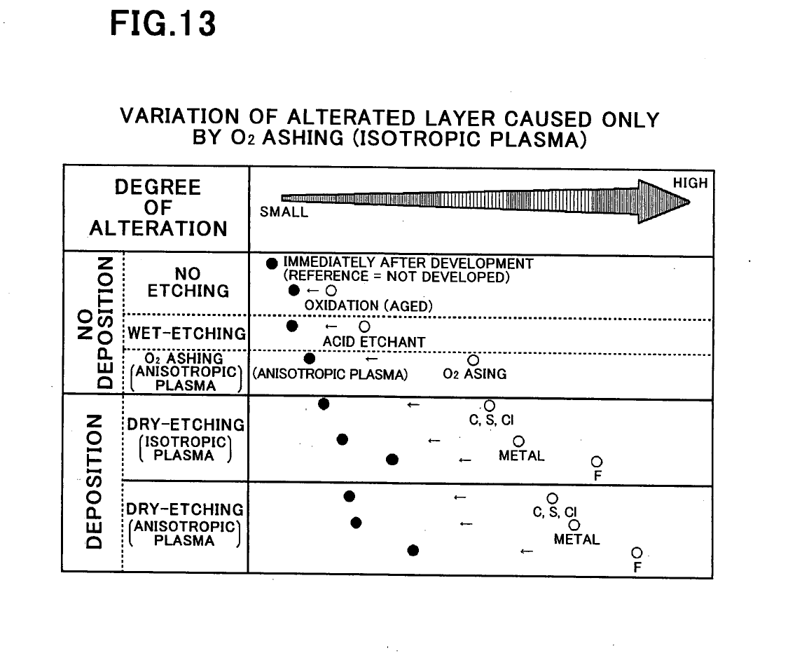

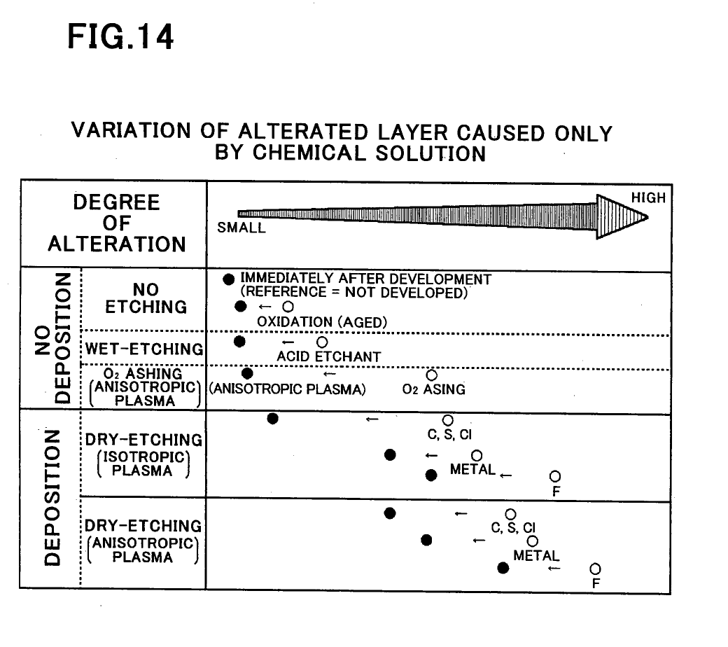

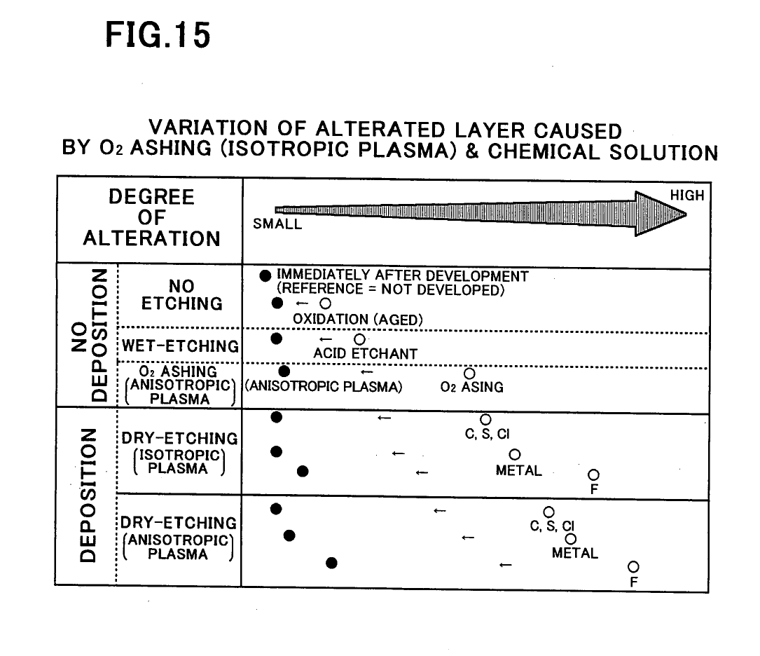

FIG. 13 illustrates variation of an alterated layer to which only an oxygen (O₂) ashing step or an isotropic plasma step is applied, FIG. 14 illustrates variation of an alterated layer to which only a step of applying chemical solution (aqueous solution containing hydroxylamine at 2%) is applied, and FIG. 15 illustrates variation of an alterated layer to which both the above-mentioned ashing step and the above-mentioned step of applying chemical solution are applied in this order.

In FIGS. 13 to 15, similarly to FIG. 12, a degree of alteration is determined in accordance with difficulty in peeling off an alterated layer with a wet step.

As illustrated in FIGS. 13 to 15, an alterated layer can be removed by carrying out any step(s). However, comparing the oxygen ashing step (isotropic plasma step) illustrated in FIG. 13 with the step of applying chemical solution (aqueous solution containing hydroxylamine at 2%) to an alterated layer, illustrated in FIG. 14, a degree of removal of an alterated layer is different from each other in accordance with a thickness and characteristic of an alterated layer.

The oxygen ashing step (isotropic plasma step) is effective to removal of an alterated layer having deposition thereon, as illustrated in FIG. 13, but is likely to damage an object. Hence, if the oxygen ashing step (isotropic plasma step) is carried out to an alterated layer having no deposition thereon, an alterated layer remains without being removed to a higher degree than a degree at which an alterated layer is removed only by the step of applying chemical solution to an alterated layer (FIG. 14).

In contrast, the step of applying chemical (aqueous solution containing hydroxylamine at 2%) to an alterated layer is less effective than the oxygen ashing step to removal of an alterated layer having deposition thereon, as illustrated in FIG. 14, but does not damage an object. Hence, if the step of applying chemical to an alterated layer is carried out to an alterated layer having no deposition thereon, an alterated layer remains without being removed to a higher degree than a degree at which an alterated layer is removed only by the oxygen ashing (isotropic plasma) step (FIG. 13).

Thus, in order to have the merits shown in FIGS. 13 and 14, the oxygen ashing step (isotropic plasma step) and the step of applying chemical (aqueous solution containing hydroxylamine at 2%) to an alterated layer are carried out in this order, as illustrated in FIG. 15.

It is understood that the method shown in FIG. 15 is effective to both an alterated layer having deposition thereon and an alterated layer having no deposition thereon, and can remove an alterated layer without damage remaining.

It is preferable that a layer lying below an organic film pattern is treated at a surface thereof for enhancing wettability thereof, in order to uniformize a fusion/deformation step such as a step of applying gas atmosphere to an organic film pattern.

For instance, wettability of an underlying film can be enhanced by carrying out the above-mentioned ashing step, that is, the oxygen (O₂) plasma step or UV ozone treatment.

For instance, the oxygen plasma step is carried out for 120 seconds in the following conditions.

Flow rate of O₂: 300 sccm

Pressure: 100 Pa

RF power: 1000 W

The UV ozone treatment is carried out by radiating ultra-violet rays to an underlying film in ozone gas atmosphere with a temperature of a substrate being kept in the range of 100 to 200 degrees centigrade, for instance.

Wettability of an underlying film can be enhanced also by various plasma-discharge steps such as fluorine gas plasma (SF₆ gas plasma, CF₄ gas plasma, CHF₃ gas plasma, etc.) or fluorine/oxygen gas plasma (SF₆/O₂ gas plasma, CF₄/O₂ gas plasma, CHF₃/O₂ gas plasma, etc.).

These plasma steps improve wettability of a surface of an underlying film not covered with an organic film pattern.

Accordingly, by carrying out these plasma steps, an organic film pattern deformed by a fusion/deformation step (for instance, the step of applying gas atmosphere to an organic film pattern) can readily reflow at a surface of an underlying film.

Pre-steps such as various plasma steps, oxygen plasma step or UV ozone step tend to damage an object in comparison with the above-mentioned step of applying chemical solution to an alterated layer. Hence, by removing an alterated layer by applying chemical solution to the alterated layer subsequently to such pre-steps as mentioned above, it would be possible to enhance wettability of an underlying film and remove an alterated layer formed at a surface of an organic film pattern, without damaging an organic film pattern. This ensures uniformly carrying out a fusion/deformation step.

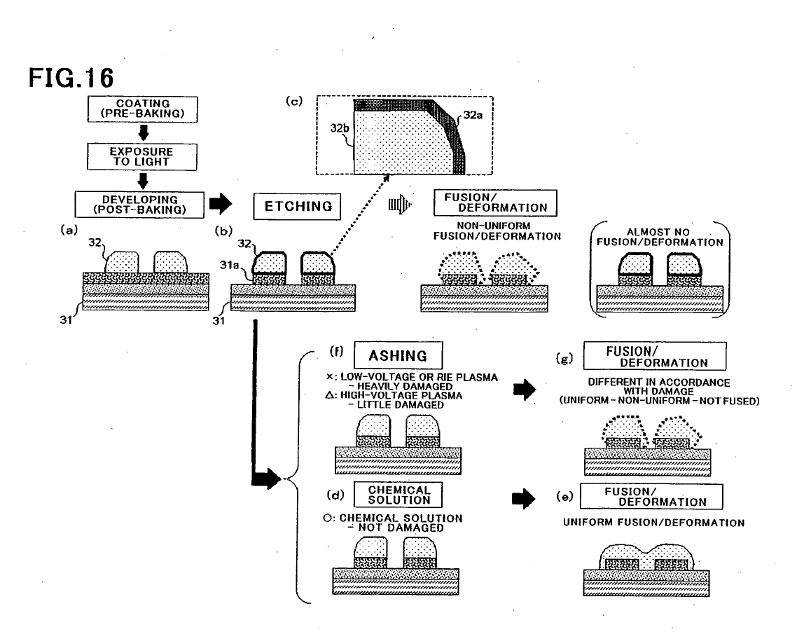

FIG. 16 illustrates the removal step in the present invention and the conventional method, to be carried out prior to a fusion/deformation step (for instance, a step of applying gas atmosphere to an organic film pattern).

FIG. 16(a) illustrates that an organic film pattern 32 is formed on a substrate 31.

FIG. 16(b) illustrates that an underlying film (for instance, an upper portion 31a of the substrate 31) is patterned by etching with the organic film pattern 32 being used as a mask.

FIG. 16(c) is an enlarged view of the organic film pattern 32 illustrated in FIG. 16(b). As illustrated in FIG. 16(c), an alterated layer 32a is formed at a surface of the organic film pattern 32, due to the etching. Hence, a non-alterated portion 32b of the organic film pattern 32 is covered with the alterated layer 32a.

FIG. 16(d) illustrates the organic film pattern 32 to which the removal step (for instance, the step of applying chemical to an organic film pattern) is applied.

As illustrated in FIG. 16(d), as a result of carrying out the removal step, the alterated layer 32a is removed. The organic film pattern 32 is hardly damaged.

FIG. 16(e) illustrates the organic film pattern 32 to which a fusion/deformation step is applied subsequently to the removal step illustrated in FIG. 16(d).

As illustrated in FIG. 16(e), the organic film pattern 32 is uniformly deformed by the fusion/deformation step.

FIG. 16(f) illustrates the organic film pattern 32 to which the conventional removal step (only ashing step) is applied.

As illustrated in FIG. 16(f), though the alterated layer 32a is removed even by the conventional removal step, the organic film pattern 32 remains damaged.

FIG. 16(g) illustrates the organic film pattern 32 to which a fusion/deformation step is applied subsequently to the conventional removal step illustrated in FIG. 16(f).

As illustrated in FIG. 16(g), the organic film pattern 32 is partially uniformly deformed by the fusion/deformation step in accordance with a degree of damage exerted on the organic film pattern 32.

The method in accordance with the fourth and fifth embodiments may be applied to, for instance, a liquid crystal display (LCD) device having a flat display panel, an electroluminescence (EL) display device, a field emission display (FED), a fluorescence display device, an active device in a plasma display panel (PDP), or a substrate including an integrated circuit.

In the fourth and fifth embodiments, the present invention is applied to a substrate. It should be noted that the present invention may be applied to a method of fabricating a liquid crystal display device (a vertical electric field type liquid crystal display device, a horizontal electric field type liquid crystal display device, a light-transmission type liquid crystal display device, a light-reflection type liquid crystal display device, and a half-transmission type liquid crystal display device), and a display device such as an EL display device, or a method of fabricating other semiconductor devices.

While the present invention has been described in connection with certain preferred embodiments, it is to be understood that the subject matter encompassed by way of the present invention is not to be limited to those specific embodiments. On the contrary, it is intended for the subject matter of the invention to include all alternatives, modifications and equivalents as can be included within the spirit and scope of the following claims.

The entire disclosure of Japanese Patent Application No. 2006-081467 filed on Mar. 23, 2006, including specification, claims, drawings and summary is incorporated herein by reference in its entirety.

What is claimed is:

1. A method of processing an organic film pattern formed on a substrate, comprising, in sequence of:
a fusion/deformation step of fusing and thereby deforming said organic film pattern; and
a third removal step of removing at least a part of the fused and deformed organic film pattern.

2. The method as set forth in claim 1, further comprising a second heating step of heating the fused and deformed organic film pattern, said second heating step being carried out after said fusion/deformation step and before said third removal step.

3. The method as set forth in claim 2, further comprising a third heating step of heating the fused and deformed organic film pattern, said third heating step being carried out after said third removal step.

4. The method as set forth in claim 3, further comprising a first heating step of heating said organic film pattern, said first heating step being carried out before said fusion/deformation step.

5. The method as set forth in claim 1, further comprising a first removal step of removing at least one of an alterated layer and a deposited layer formed on a surface of said organic film pattern, said first removal step being carried out before said fusion/deformation step.

6. The method as set forth in claim 5, further comprising a second heating step of heating the fused and deformed organic film pattern, said second heating step being carried out after said fusion/deformation step and before said third removal step.

7. The method as set forth in claim 6, further comprising a third heating step of heating the fused and deformed organic film pattern, said third heating step being carried out after said third removal step.

8. The method as set forth in claim 7, further comprising a first heating step of heating said organic film pattern, said first heating step being carried out before said first removal step.

9. The method as set forth in claim 5, further comprising a second removal step of removing a part of said organic film pattern, said second removal step being carried out after said first removal step and before said fusion/deformation step.

10. The method as set forth in claim 9, further comprising a second heating step of heating the fused and deformed organic film pattern, said second heating step being carried out after said fusion/deformation step and before said third removal step.

11. The method as set forth in claim 10, further comprising a third heating step of heating the fused and deformed organic film pattern, said third heating step being carried out after said third removal step.

12. The method as set forth in claim 11, further comprising a first heating step of heating said organic film pattern, said first heating step being carried out before said first removal step.

13. The method as set forth in claim 1, further comprising a temperature controlling step of keeping constant a temperature at which said substrate is processed, said temperature controlling step being carried out immediately before, said fusion/deformation step.

14. The method as set forth in claim 1, further comprising originally forming said organic film pattern on said substrate by printing.

15. The method as set forth in claim 1, further comprising originally forming said organic film pattern on said substrate by photolithography.

16. The method as set forth in claim 1, further comprising originally forming a photosensitive organic film as said organic film pattern on said substrate.

17. The method as set forth in claim 16, wherein said photosensitive organic film is comprised of one of a positive type photosensitive organic film and a negative type photosensitive organic film.

18. The method as set forth in claim 17, wherein said positive type photosensitive organic film contains novolak resin as a principal constituent.

19. The method as set forth in claim 16, wherein said photosensitive organic film is soluble in alkali, if exposed to light.

20. The method as set forth in claim 9, wherein one of said alterated layer and said deposited layer is selectively removed in at least one of said first and second removal steps.

21. The method as set forth in claim 9, wherein one of said alterated layer and said deposited layer is selectively removed, and a non-alterated portion of said organic film pattern is caused to appear in at least one of said first and second removal steps.

22. The method as set forth in claim 9, wherein a non-alterated portion of said organic film pattern is partially removed in at least one of said first and second removal steps.

23. The method as set forth in claim 1, wherein one of an alterated layer and a deposited layer formed on the fused and deformed organic film pattern, or one of an alterated layer and a deposited layer formed around the fused and deformed organic film pattern is selectively removed in said third removal step.

24. The method as set forth in claim 1, wherein one of an alterated layer and a deposited layer formed on the fused and deformed organic film pattern, or one of an alterated layer and a deposited layer formed around the fused and deformed organic film pattern is selectively removed in said third removal step for causing the fused and deformed organic film pattern to appear.

25. The method as set forth in claim 23, wherein the fused and deformed organic film pattern is partially removed after said one of an alterated layer and a deposited layer was removed.

26. The method as set forth in claim 4, wherein at least one of water, acid and alkali having penetrated said organic film pattern is removed in at least one of said first, second and third heating steps.

27. The method as set forth in claim 4, wherein, when an adhesive force between said organic film pattern and said substrate or an underlying film is lowered, at least one of said first, second and third heating steps enhances said adhesive force.

28. The method as set forth in claim 1, wherein a heating step for forming said organic film pattern is carried out at a temperature equal to or smaller than a temperature at which said organic film pattern is cross-linked.

29. The method as set forth in claim 4, wherein said organic film pattern is heated at a temperature equal to or smaller than a temperature at which said organic film pattern is cross-linked, during a heating step for forming said organic film pattern and said first heating step.

30. The method as set forth in claim 2, wherein said organic film pattern is heated at a temperature equal to or smaller than a temperature at which said organic film pattern is cross-linked, during a heating step for forming said organic film pattern and said second heating step.

31. The method as set forth in claim 3, wherein said organic film pattern is heated at a temperature equal to or smaller than a temperature at which said organic film pattern is cross-linked, during a heating step for forming said organic film pattern and said third heating step.

32. The method as set forth in claim 4, wherein said organic film pattern is heated at a temperature equal to or smaller than a temperature at which said organic film pattern is cross-linked, in a heating step for forming said organic film pattern, said first heating step, said second heating step, and said third heating step.

33. The method as set forth in claim 1, wherein a heating step for forming said organic film pattern is carried out at a temperature in the range of 50 to 150 degrees centigrade both inclusive.

34. The method as set forth in claim 33, wherein a heating step for forming said organic film pattern is carried out at a temperature in the range of 100 to 130 degrees centigrade both inclusive.

35. The method as set forth in claim 4, wherein said first heating step is carried out at a temperature lower than a temperature at which said second heating step is carried out.

36. The method as set forth in claim 4, wherein a heating step for forming said organic film pattern and said first heating step are carried out at a temperature lower than a temperature at which said second heating step is carried out.

37. The method as set forth in claim 3, wherein said second heating step is carried out at a temperature lower than a temperature at which said third heating step is carried out.

38. The method as set forth in claim 2, wherein a heating step for forming said organic film pattern, said first heating step, and said second heating step are carried out at a temperature lower than a temperature at which said third heating step is carried out.

39. The method as set forth in claim 4, wherein said first heating step is carried out at a temperature lower than a temperature at which said third heating step is carried out.

40. The method as set forth in claim 4, wherein a heating step for forming said organic film pattern and said first heating step are carried out at a temperature lower than a temperature at which said third heating step is carried out.

41. The method as set forth in claim 4, wherein a heating step for forming said organic film pattern, said first heating step, said second heating step, and said third heating step are carried out for 60 to 300 seconds both inclusive.

42. The method as set forth in claim 5, wherein said alterated layer formed on said organic film pattern is caused by at least one of aging, thermal oxidation and heat curing.

43. The method as set forth in claim 5, wherein said alterated layer formed on said organic film pattern is caused by wet-etching.

44. The method as set forth in claim 5, wherein said alterated layer formed on said organic film pattern is caused by at least one of dry-etching and ashing.

45. The method as set forth in claim 5, wherein said alterated layer formed on said organic film pattern is caused by deposition resulted from dry-etching.

46. The method as set forth in claim 5, wherein said deposited layer formed on said organic film pattern is caused by dry-etching.

47. The method as set forth in claim 1, wherein an area of said organic film pattern is increased in said fusion/deformation step

48. The method as set forth in claim 1, wherein organic film patterns disposed adjacent to each other are joined in said fusion/deformation step

49. The method as set forth in claim 1, wherein said organic film pattern is planarized in said fusion/deformation step

50. The method as set forth in claim 1, wherein said organic film pattern is deformed in said fusion/deformation step such that said organic film pattern is turned into an electrically insulating film covering therewith a circuit pattern formed on said substrate.

51. The method as set forth in claim 1, wherein said organic film pattern is deformed in said fusion/deformation step by making contact with organic solution to cause fusion reflow.

52. The method as set forth in claim 52, wherein said organic solution contains at least one of the following organic solvents (R indicates an alkyl group or a substitutional alkyl group, Ar indicates a phenyl group or an aromatic ring other than a phenyl group):
alcohol (R—OH);
alkoxyalcohol;
ether (R—O—R, Ar—O—R, Ar—O—Ar);
ester;
ketone;
glycol;
alkylene glycol; and
glycol ether.

53. The method as set forth in claim 51, wherein said organic film pattern is exposed to vapor of said organic solvent in said fusion reflow.

54. The method as set forth in claim 51, wherein said organic film pattern is immersed into said organic solvent in said fusion reflow.

55. The method as set forth in claim 51, wherein said fusion/deformation step or said fusion reflow is comprised of a step of applying gas atmosphere to said organic film pattern.

56. The method as set forth in claim 55, wherein said step of applying gas atmosphere to said organic film patter is carried out in gas atmosphere of said organic solvent.

57. The method as set forth in claim 9, wherein at least a part of at least one of said first, second and third removal steps is comprised of a step of applying chemical solution to said organic film pattern.

58. The method as set forth in claim 9, wherein at least a part of at least one of said first, second and third removal steps is comprised of a step of ashing said organic film pattern.

59. The method as set forth in claim 1, wherein said third removal step is comprised of a step of twice applying chemical solution to said organic film pattern through the use of two different chemical solutions.

60. The method as set forth in claim 5, wherein said first removal step is comprised of a first step of applying chemical solution to said organic film pattern.

61. The method as set forth in claim 9, wherein at least one of said second and third removal steps is comprised of a second step of applying chemical solution to said organic film pattern.

62. The method as set forth in claim 5, wherein said first removal step is comprised of, in sequence of, ashing said organic film pattern, and a first step of applying chemical solution to said organic film pattern.

63. The method as set forth in claim 9, wherein at least one of said second and third removal steps is comprised of, in sequence of, ashing said organic film pattern, and a second step of applying chemical solution to said organic film pattern.

64. The method as set forth in claim 1, wherein said third removal step is comprised of a first step of applying chemical solution to said organic film pattern, and a second step of applying chemical solution to said organic film pattern.

65. The method as set forth in claim 9, wherein each of said first, second and third removal steps is comprised of a step of applying chemical solution to said organic film pattern.

66. The method as set forth in claim 58, wherein films formed on said substrate are etched in said ashing step through the use of at least one of plasma, ozone and ultraviolet rays.

67. The method as set forth in claim 9, further comprising an exposure step of exposing said organic film pattern to light immediately before at least one of said first, second and third removal steps.

68. The method as set forth in claim 60, further comprising an exposure step of exposing said organic film pattern to light immediately before at least one of said first and second steps.

69. The method as set forth in claim 63, further comprising a back-exposure step of exposing said organic film pattern to light through a lower surface of said substrate between said fusion/deformation step and said third removal step or between said fusion/deformation step and said second step.

70. The method as set forth in claim 67, wherein said organic film pattern is exposed to light in said exposure step only in an area associated with a predetermined area of said substrate.

71. The method as set forth in claim 69, wherein said organic film pattern is exposed to light in said back-exposure step only in an area associated with a predetermined area of said substrate.

72. The method as set forth in claim 67, wherein said organic film pattern is exposed to light in said exposure step in an area associated with a predetermined area of said substrate by radiating light entirely over said area or by scanning said area with spot-light.

73. The method as set forth in claim 70, wherein said predetermined area has an area equal to or greater than 1/10 of an area of said substrate.

74. The method as set forth in claim 67, wherein said organic film pattern is exposed to ultra-violet rays, fluorescence, or natural light in said exposure step.

75. The method as set forth in claim 68, wherein at least one of said first and second steps is comprised of a development step of developing said organic film pattern through the use of chemical solution having a function of developing said organic film pattern.

76. The method as set forth in claim 68, wherein at least one of said first and second steps is comprised of an overdevelopment step of carrying out n-th development of said organic film pattern through the use of chemical solution having a function of developing said organic film pattern, wherein n indicates an integer equal to or greater than two.

77. The method as set forth in claim 68, wherein at least one of said first and second steps is comprised of a development step of developing said organic film pattern through the use of chemical solution not having a function of developing said organic film pattern, but having a function of fusing said organic film pattern.

78. The method as set forth in claim 77, wherein said chemical solution is comprised of a solution obtained by diluting separating agent.

79. The method as set forth in claim 75, wherein said chemical solution having a function of developing said organic film pattern is comprised of TMAH (tetramethylammonium hydroxide) or inorganic alkaline aqueous solution.

80. The method as set forth in claim 79, wherein said inorganic alkaline aqueous solution is one of NaOH aqueous solution and CaOH aqueous solution.

81. The method as set forth in claim 1, wherein said organic film pattern formed originally on said substrate has at least two portions having different thicknesses from one another.

82. The method as set forth in claim 9, wherein said organic film pattern formed originally on said substrate has at least two portions having different thicknesses from one another, and a thin portion among said portions of said organic film pattern is further thinned in at least one of said first, second and third removal steps.

83. The method as set forth in claim 9, wherein said organic film pattern formed originally on said substrate has at least two portions having different thicknesses from one another, and a thin portion among said portions of said organic film pattern is removed in at least one of said first, second and third removal steps.

84. The method as set forth in claim 1, wherein said organic film pattern is kept not exposed to light until said fusion/deformation step is carried out after said organic film pattern was originally formed on said substrate.

85. The method as set forth in claim 67, wherein said organic film pattern is kept not exposed to light until said exposure step is carried out after said organic film pattern was originally formed on said substrate.

86. The method as set forth in claim 1, further comprising a patterning step of patterning an underlying film formed below said organic film pattern, with said organic film pattern being used as a mask, before said fusion/deformation step is applied to said organic film pattern.

87. The method as set forth in claim 1, further comprising a patterning step of patterning an underlying film formed below said organic film pattern, with said organic film pattern being used as a mask, before said fusion/deformation step, said first removal step or said first heating step is applied to said organic film pattern.

88. The method as set forth in claim 1, further comprising a patterning step of patterning an underlying film formed below said organic film pattern, with said organic film pattern being used as a mask, after said second heating step, said third removal step or said third heating step was applied to said organic film pattern.

89. The method as set forth in claim 1, further comprising a patterning step of patterning an underlying film formed below said organic film pattern, with said organic film pattern being used as a mask, after said third removal step was applied to said organic film pattern.

90. The method as set forth in claim 86, wherein said underlying film is patterned to be tapered or step-liked in said patterning step.

91. The method as set forth in claim 86, wherein said underlying film is comprised of a plurality of films, and some of said films are patterned into different patterns from one another in said patterning step.

92. The method as set forth in claim 68, wherein said chemical solution used in said first or second step contains at least acid chemical.

93. The method as set forth in claim 68, wherein said chemical solution used in said first or second step contains at least organic solvent.

94. The method as set forth in claim 68, wherein said chemical solution used in said first or second step contains at least alkaline chemical.

95. The method as set forth in claim 68, wherein said chemical solution used in said first or second step contains at least amine.

96. The method as set forth in claim 68, wherein said chemical solution used in said first or second step contains at least organic solvent and amine.

97. The method as set forth in claim 68, wherein said chemical solution used in said first or second step contains at least amine and water.

98. The method as set forth in claim 68, wherein said chemical solution used in said first or second step contains at least alkaline chemical and amine.

99. The method as set forth in claim 95, wherein said amine is selected from a group consisting of monoethyl amine, diethyl amine, triethyl amine, monoisopyl amine, diisopyl amine, triisoply amine, monobutyl amine, dibutyl amine, tributyl amine, hydroxylamine, diethylhydroxylamine, diethylhydroxylamine anhydride, pyridine, and picoline.

100. The method as set forth in claim 95, wherein said chemical solution contains said amine in the range of 0.01 to 10 weight % both inclusive.

101. The method as set forth in claim 100, wherein said chemical contains said amine in the range of 0.05 to 5 weight % both inclusive.

102. The method as set forth in claim 101, wherein said chemical contains said amine in the range of 0.05 to 2.0 weight % both inclusive.

103. The method as set forth in claim 68, wherein said chemical solution used in said first or second step contains anticorrosive.

104. The method as set forth in claim 1, wherein said organic film pattern is formed by patterning an underlying film thereof with said organic film pattern being used as a mask before said fusion/deformation step was carried out.

105. The method as set forth in claim 104, further comprising a step of further patterning said underlying film with said organic film pattern being used as a mask after said third removal step was carried out.

106. The method as set forth in claim 1, wherein at least one of a step of exposing to light, a development step, a wet-etching step and dry-etching step is applied to said organic film pattern before said fusion/deformation step is carried out.

107. The method as set forth in claim 1, further comprising a step of forming a circuit having a high resistance to dielectric breakdown.

108. A method of fabricating a device, including a step of carrying out the method as defined in any one of claims 1 to 12.

109. The method as set forth in claim 108, wherein said device is comprised of a display device.

110. The method as set forth in claim 108, wherein said device is comprised of a semiconductor device.

111. The method as set forth in claim 108, wherein said device is comprised of a liquid crystal display device.

112. The method as set forth in claim 108, wherein said device is comprised of an EL display device.

113. The method as set forth in claim 108, wherein said device is comprised of a field emission display device.

114. The method as set forth in claim 108, wherein said device is comprised of a plasma display device.
